(19) United States
(12) Patent Application Publication
(10) Pub. No.: US 2026/0351911 A1
(43) Pub. Date: Nov. 5, 2026

(54) COMPONENT CONNECTION STRUCTURE AND CONNECTION COMPONENT

(71) Applicant: YAZAKI CORPORATION, Tokyo (JP)

(72) Inventors: Ryu Senoo, Kakegawa-shi (JP); Hirotaka Mukasa, Kakegawa-shi (JP); Kazuhiko Tsuchiya, Kakegawa-shi (JP)

(21) Appl. No.: 19/344,517

(22) Filed: Sep. 30, 2025

(30) Foreign Application Priority Data
Oct. 1, 2024 (JP) 2024-172521

(51) Int. Cl. H01R 25/16; H05K 7/20

(52) U.S. Cl. CPC H01R 25/161; H05K 7/2049

(57) ABSTRACT

A component connection structure includes: a bus bar; a connection target component; and a connection component that connects the bus bar and the connection target component. The connection component includes a first end facing the bus bar in a first direction. The first end includes: an abutting portion that abuts the bus bar; and a recess that is recessed in a direction away from the bus bar in the first direction with respect to the abutting portion. The connection component is fixed to the bus bar in a state in which the recess is filled with a heat transfer member having a higher thermal conductivity than the connection component.

### TECHNICAL FIELD

Embodiments of the present invention relate to a component connection structure and a connection component.

Priority is claimed on Japanese Patent Application No. 2024-172521 filed in Japan on Oct. 1, 2024, the content of which is incorporated herein by reference.

### BACKGROUND ART

An electrical connection unit having a housing that accommodates electronic components and a bus bar attached to the housing in a standing posture is known.

### PRIOR ART DOCUMENTS

### Patent Documents

[Patent Document 1] Japanese Unexamined Patent Application, First Publication No. 2024-037492

### SUMMARY OF THE INVENTION

### Problems to be Solved by the Invention

An object of an electrical connection unit is to enhance heat transfer properties between a connection component for fixing an electronic component to a bus bar and the bus bar.

One embodiment provides a component connection structure and a connection component that can enhance heat transfer properties between the connection component and a bus bar.

### Means for Solving the Problem

A component connection structure according to an embodiment includes a component connection structure includes: a bus bar; a connection target component; and a connection component that connects the bus bar and the connection target component. The connection component includes a first end facing the bus bar in a first direction. The first end includes: an abutting portion that abuts the bus bar; and a recess that is recessed in a direction away from the bus bar in the first direction with respect to the abutting portion. The connection component is fixed to the bus bar in a state in which the recess is filled with a heat transfer member having a higher thermal conductivity than the connection component.

A connection component according to an embodiment includes a first end facing a bus bar in a first direction, and the first end includes an abutting portion abutting the bus bar and a recess recessed in a direction away from the bus bar in the first direction with respect to the abutting portion.

### Effects of Invention

According to an embodiment, heat transfer properties between the connection component and the bus bar can be enhanced.

### BRIEF DESCRIPTION OF THE DRAWINGS

FIG. 1 A cross-sectional view illustrating an electrical connection unit of an embodiment.

FIG. 2 A perspective view for describing a main body of the embodiment.

FIG. 3 A perspective view for describing a subunit of the embodiment.

FIG. 4 A partially exploded perspective view of the subunit of the embodiment.

FIG. 5 A perspective view for describing an electronic component and a connection component of the embodiment.

FIG. 6 A perspective view for describing the electronic component and the connection component of the embodiment.

FIG. 7 A perspective view illustrating the connection component of the embodiment.

FIG. 8 A perspective view illustrating a routing board of the embodiment.

FIG. 9 A partially exploded perspective view of the routing board of the embodiment.

FIG. 10 A plan view illustrating the routing board of the embodiment.

FIG. 11 A partially exploded perspective view of a connection unit of the embodiment.

FIG. 12 A bottom view illustrating the routing board of the embodiment.

FIG. 13 A cross-sectional view taken along line A-A of the structure illustrated in FIG. 10.

FIG. 14 A perspective view illustrating a three-dimensional routing structure of a bus bar of the embodiment.

FIG. 15 A plan view illustrating the three-dimensional routing structure of the bus bar of the embodiment.

FIG. 16 A cross-sectional view for describing a structure related to the connection component of the embodiment.

FIG. 17 A perspective view for describing the connection component of the embodiment.

FIG. 18 A perspective view for describing a first constitution in which a recess is provided in the connection component of the embodiment.

FIG. 19 A side view of the constitution of FIG. 18 as viewed from a Y direction.

FIG. 20 A plan view of the constitution of FIG. 18 as viewed from a Z direction.

FIG. 21 A perspective view for describing a second constitution in which a recess is provided in the connection component of the embodiment.

FIG. 22 A plan view corresponding to FIG. 20 illustrating a first modification example of the recess.

FIG. 23 A plan view corresponding to FIG. 20 illustrating a second modification example of the recess.

### EMBODIMENTS FOR CARRYING OUT THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only a part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

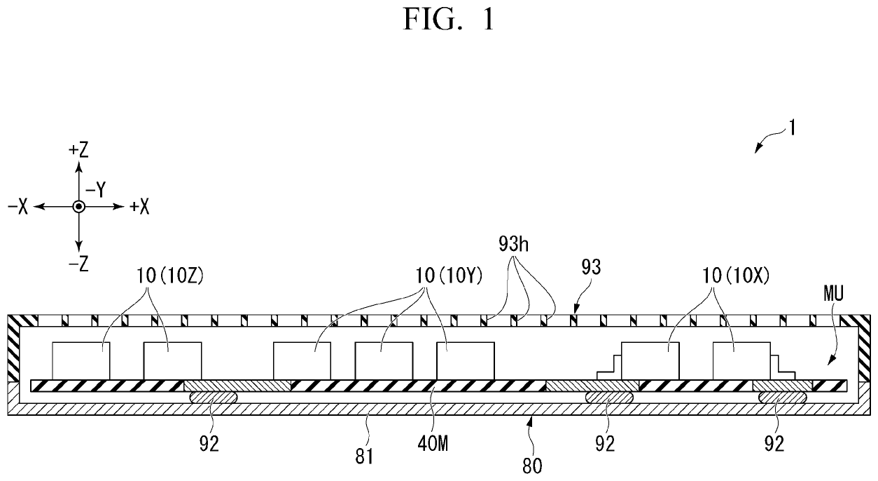

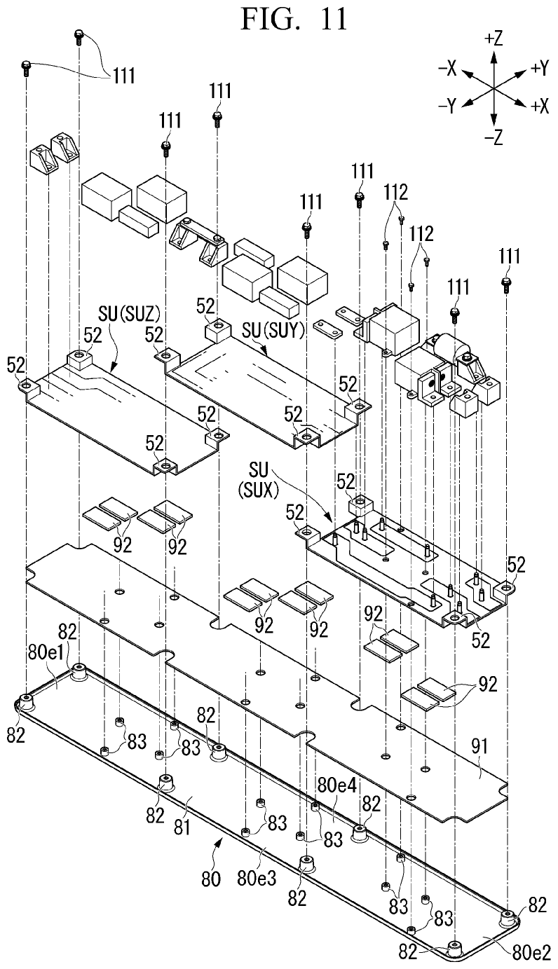

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 11). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 11). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”. The X direction is an example of a “second direction”. The Y direction is an example of a “third direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### Embodiment

### <1. Constitution of Electrical Connection Unit>

FIG. 1 is a cross-sectional view illustrating an electrical connection unit 1 of an embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a main body MU, a metal plate (support member) 80, an insulating sheet 91 (see FIG. 11), a plurality of heat transfer members 92, and an insulating cover 93.

### <2. Main Body>

First, the main body MU will be described.

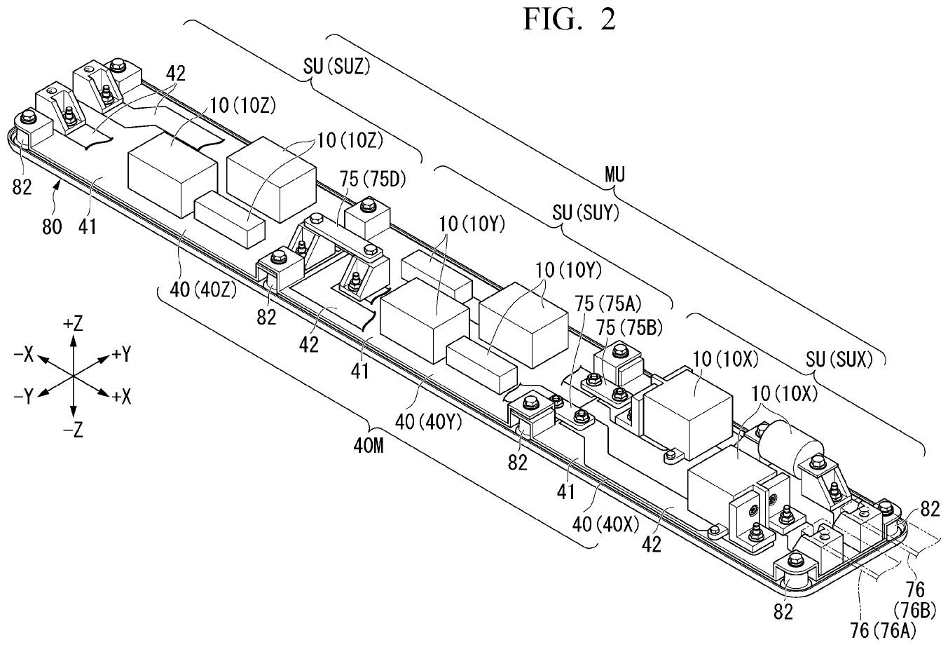

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU (subunits SUX, SUY, and SUZ). Each subunit SU may be referred to as a “circuit constitution body”.

The subunit SUX has an electrical first function. The subunit SUX includes, for example, a plurality of electronic components 10X and a first routing board 40X. The plurality of electronic components 10X are electrically connected to the first routing board 40X.

The subunit SUY has an electrical second function. The second function is a function different from the first function. The subunit SUY includes, for example, a plurality of electronic components 10Y and a second routing board 40Y. The plurality of electronic components 10Y are electrically connected to the second routing board 40Y.

The subunit SUZ has an electrical third function. The third function is a function different from the first function and the second function. The subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the subunit SUX is disposed on the +X direction side with respect to the subunit SUY. The subunit SUX and the subunit SUY are electrically connected via a plurality of coupling bus bars 75 extending between the first routing board 40X and the second routing board 40Y. On the other hand, the subunit SUZ is disposed on the −X direction side with respect to the subunit SUY. The subunit SUZ and the subunit SUY are electrically connected via a plurality of coupling bus bars 75 (only one is illustrated in FIG. 2) extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. As a result, one large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the subunit SUX, the subunit SUY, and the subunit SUZ are not distinguished, the subunits are simply referred to as “subunit SU”. In addition, in a case where the electronic component 10X, the electronic component 10Y, and the electronic component 10Z are not distinguished, the electronic components are simply referred to as “electronic component 10”. In a case where the first routing board 40X, the second routing board 40Y, and the third routing board 40Z are not distinguished, the routing boards are simply referred to as “routing board 40”.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

### <3. Constitution of Subunit>

Next, a constitution of the subunit SU will be described.

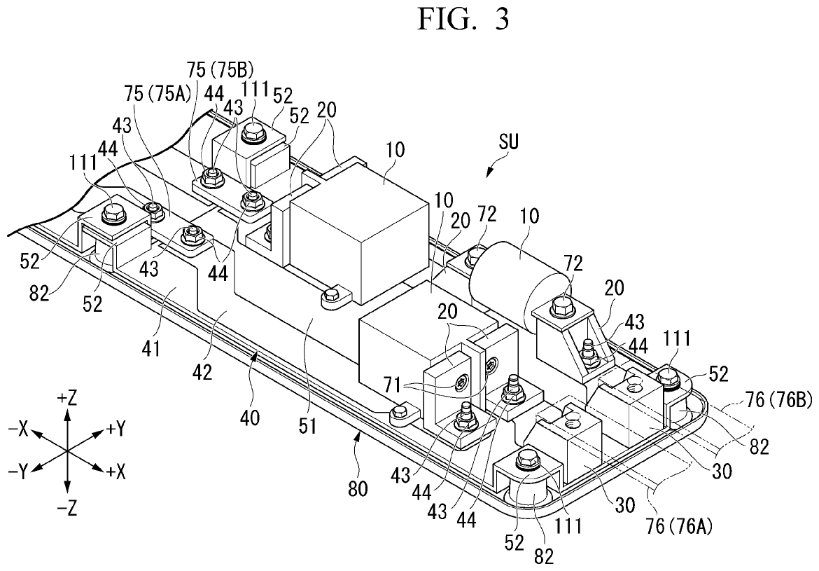

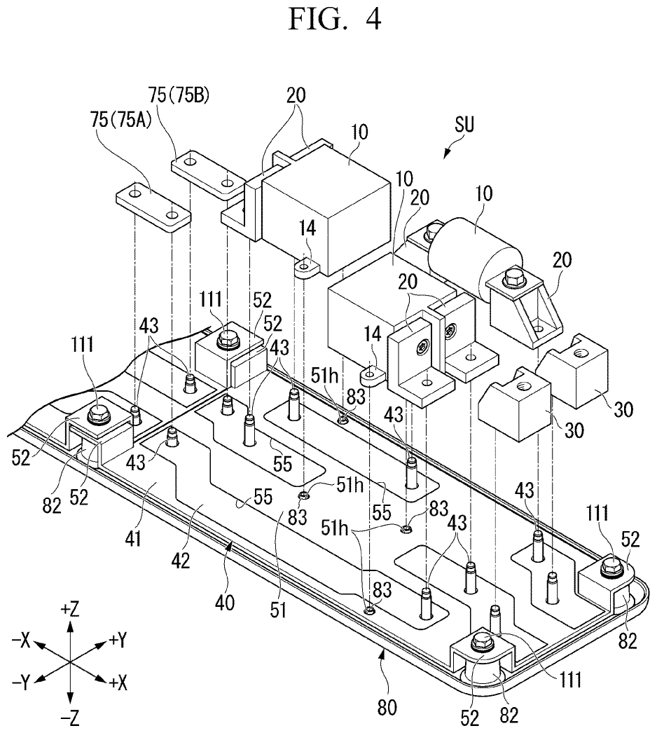

FIG. 3 is a perspective view for describing the subunit SU. FIG. 4 is a partially exploded perspective view of the subunit SU. The subunit SU includes, for example, a plurality of electronic components 10, a plurality of connection components 20 for component connection, a plurality of connection components 30 for external connection, and a routing board 40. The connection components 20 and 30 are members forming an energization path in the vertical direction. The connection components 20 and 30 may be referred to as “vertical routing members”.

### <3.1 Electronic Component and Connection Component for Component Connection>

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10.

The connection component 20 is a component that electrically connects the electronic component 10 to the routing board 40. The connection component 20 forms a part of an energization path in the subunit SU. The connection component 20 is made of a metal (for example, copper or a copper alloy). The connection component 20 may be referred to as a “metal component”. Hereinafter, a first-type connection component 20M and a second-type connection component 20N will be described as examples of the connection component 20. Similarly, a connection component 30 or 100 that will be described later may be referred to as a “metal component”.

### <3.1.1 First-Type Electronic Component>

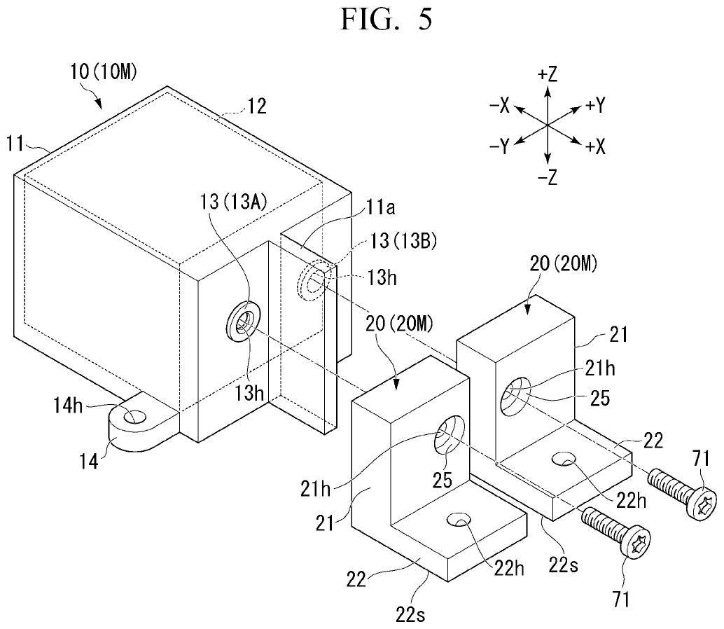

FIG. 5 is a perspective view illustrating the first-type electronic component 10M and the first-type connection component 20M. The first-type electronic component 10M is an electronic component in which a plurality of terminals 13 are disposed to be arranged at one end of the electronic component 10M. The electronic component 10M includes, for example, a case 11, a component body 12, a plurality of terminals 13, and a plurality of attachment portions 14.

### (Case)

The case 11 is an outer member that forms most of the outer shape of the electronic component 10M. The case 11 is made of, for example, synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, a part of the insulating rib 11a is disposed between first portions 21 (that will be described later) of two connection components 20M connected to the electronic component 10M. The insulating rib 11a electrically insulates the first portions 21 of the two connection components 20M connected to the electronic component 10M from each other.

### (Component Body)

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

### (Terminal)

The terminal 13 is an electrical connection portion exposed to the outside of the case 11. The terminal 13 is electrically connected to the component body 12 inside the case 11. In the present embodiment, the electronic component 10M includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side.

In the present embodiment, the terminal 13A and the terminal 13B are provided at one end of the electronic component 10M in the horizontal direction (for example, the X direction). The terminal 13A and the terminal 13B are disposed to be arranged in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the X direction). An inner circumferential surface of the attachment hole 13h of the electronic component 10M has a screw groove.

### (Attachment Portion)

The attachment portion 14 is a portion for fixing the electronic component 10M. The attachment portion 14 has an attachment hole 14h to which a fastening member 112 (for example, a screw or a bolt; and see FIG. 11) that will be described later is attached. The attachment hole 14h is open in the Z direction. The attachment hole 14h is an insertion hole through which the fastening member 112 passes. A fixing destination of the attachment portion 14 will be described later.

### <3.1.2 First-Type Connection Component>

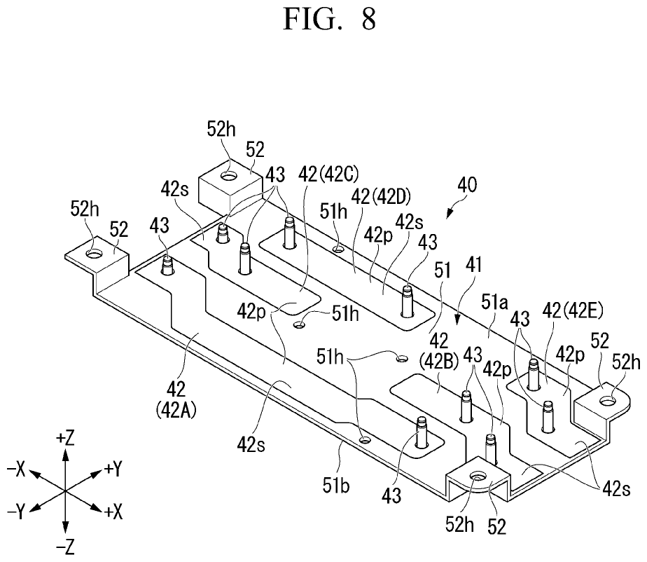

The first-type connection component 20M is a component disposed between the first-type electronic component 10M and the routing board 40. In the present embodiment, the connection component 20M electrically connects the electronic component 10M to a bus bar 42 (see FIG. 8) included in the routing board 40. The connection component 20M includes, for example, a first portion 21 rising above the routing board 40 and a second portion 22 disposed along the routing board 40.

### (First Portion)

The first portion 21 of the connection component 20M is a portion connected to the terminal 13 of the electronic component 10M. The first portion 21 is a plate-shaped or rectangular parallelepiped portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction).

The first portion 21 of the connection component 20M has an attachment hole (hereinafter, for convenience of description, referred to as a second attachment hole) 21h through which the fastening member 71 (for example, a screw or a bolt) passes. The second attachment hole 21h is open in the horizontal direction (for example, the X direction). The first portion 21 has a recess 25 around the second attachment hole 21h. The recess 25 is an accommodation portion that accommodates a head of the fastening member 71 inserted into the second attachment hole 21h. The second attachment hole 21h faces the terminal 13 of the electronic component 10M in the X direction. The fastening member 71 that has passed through the second attachment hole 21h is engaged with the attachment hole 13h of the terminal 13 of the electronic component 10M, and thus the first portion 21 is physically and electrically connected to the terminal 13 of the electronic component 10M. The first portion 21 need not have the recess 25.

FIG. 17 is a perspective view illustrating a constitution that can be adopted in the connection components 20, 30, and 100 of the present embodiment. In FIG. 17, the connection components 20, 30, and 100 are collectively denoted by the reference number 20A, and the first portion, the first attachment hole, the second attachment hole, the second portion, and the third attachment hole of each connection component are respectively denoted by the reference numbers 21A, 21hA, 21hB, 22A, and 22hA, respectively. FIG. 17 illustrates only a constitution common to the connection components.

The first portion 21A illustrated in FIG. 17 includes a first attachment portion 21fA including the first attachment hole 21hA through which a connection target component (the second-type electronic component 10N, the bus bars 75 and 76, and the like) can be attached (fixed) from the Z direction by using a fastening member F1 (fastening member 72 or the like) provided in the Z direction, and a second attachment portion 21fB including a second attachment hole 21hB through which another connection target component (first type electronic component 10M or the like) can be attached (fixed) from the X direction by using a fastening member F2 (fastening member 71 or the like) provided in the X direction.

The second portion 22A includes a third attachment portion 22fA including a third attachment hole 22hA through which the second portion 22A can be attached (fixed) to the bus bar 42 (see FIG. 8) by using a fastening member (such as the fastening member 43) provided in the Z direction.

The first attachment portion 21fA and the second attachment portion 21fB in the first portion 21A are disposed to be shifted from each other in the Y direction. A shift D1 in the Y direction between the first attachment portion 21fA and the second attachment portion 21fB corresponds to an interval in the Y direction between a center Al of the first attachment hole 21hA and a center B1 of the second attachment hole 21hB. The shift D1 is preferably set such that the first attachment hole 21hA and the second attachment hole 21hB do not overlap each other in the Y direction.

The second attachment portion 21fB of the first portion 21A and the third attachment portion 22fA of the second portion 22A are disposed to be shifted from each other in the Y direction. A shift D2 in the Y direction between the second attachment portion 21fB and the third attachment portion 22fA corresponds to an interval in the Y direction between a center B1 of the second attachment hole 21hB and a center C1 of the third attachment hole 22hA. The shift D2 is preferably set such that the second attachment hole 21hB and the third attachment hole 22hA do not overlap each other in the Y direction.

The magnitudes of the shifts D1 and D2 are different from each other. Therefore, the first attachment portion 21fA of the first portion 21A and the third attachment portion 22fA of the second portion 22A are disposed to be shifted from each other in the Y direction. The shift in the Y direction between the first attachment portion 21fA and the third attachment portion 22fA corresponds to an interval in the Y direction between the center Al of the first attachment hole 21hA and the center C1 of the third attachment hole 22hA.

### (Second Portion)

Referring to FIG. 5 again, the second portion 22 of the connection component 20M is a portion connected to the bus bar 42 (see FIG. 8). The second portion 22 protrudes in the horizontal direction (for example, the X direction) from an end (base end) on the −Z direction side of the first portion 21. The second portion 22 is a plate portion provided in the horizontal direction. The second portion 22 is adjacent (overlaps) to the bus bar 42 in the Z direction, and is connected to the bus bar 42 from the Z direction. A lower surface (a surface on the −Z direction side, including the lower surface of the first portion 21) 22s of the second portion 22 faces an upper surface (a surface on the +Z direction side) 42s of the bus bar 42 in the Z direction. The lower surface 22s of the connection component 20M abuts on the upper surface 42s of the bus bar 42. In this state, the connection component 20M is fixed to the bus bar 42. The respective lower surfaces 22s, 32s, and 102s of the connection components 20, 30, and 100 of the present embodiment may be collectively referred to as facing surfaces 22As facing the upper surface 42s of the bus bar 42 in the Z direction.

The second portion 22 of the connection component 20M is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20M has a third attachment hole 22h through which the fastening member 43 passes. The third attachment hole 22h is open in the Z direction. In the second portion 22, the fastening member 43 that will be described later passes through the third attachment hole 22h. An engagement member 44 (for example, a nut; and see FIG. 3) is engaged with the tip of the fastening member 43 that has passed through the third attachment hole 22h, and thus the second portion 22 is fixed to the bus bar 42. In the present embodiment, the first portion 21 and the second portion 22 form one L-shaped connection component 20M.

### <3.1.3 Second-Type Electronic Component>

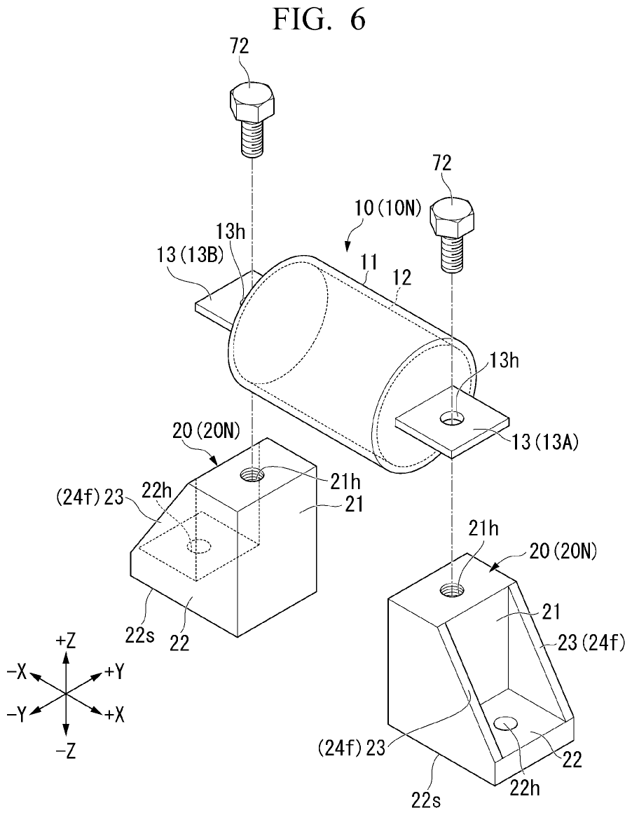

FIG. 6 is a perspective view illustrating the second-type electronic component 10N and the second-type connection component 20N. The second-type electronic component 10N is an electronic component in which two terminals 13 are separately disposed at both ends in the horizontal direction of the electronic component 10N. The electronic component 10N includes, for example, a case 11, a component body 12, and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminal 13A and the terminal 13B are disposed separately at both ends in the horizontal direction (for example, the X direction) of the electronic component 10N. Each terminal 13 has an attachment hole 13h to which a fastening member 72 (for example, a screw or a bolt) that will be described later is attached. The attachment hole 13h is open in the Z direction. For example, the attachment hole 13h of each terminal 13 is an insertion hole through which the fastening member 72 passes.

### <3.1.4 Second-Type Connection Component>

The second-type connection component 20N is a component that electrically connects the second-type electronic component 10N and the routing board 40. In the present embodiment, the connection component 20N electrically connects the electronic component 10N to the bus bar 42 (see FIG. 8) included in the routing board 40. The connection component 20N includes, for example, a first portion 21, a second portion 22, and a third portion 23.

### (First Portion)

The first portion 21 of the connection component 20N is a portion connected to the terminal 13 of the electronic component 10N. The first portion 21 is a rectangular parallelepiped portion extending in the Z direction. The first portion 21 is a standing portion that stands in the Z direction with respect to the routing board 40 (for example, with respect to the bus bar 42). The first portion 21 is adjacent (overlaps) to the terminal 13 of the electronic component 10N in the Z direction, and is connected to the terminal 13 of the electronic component 10N from the Z direction. The first portion 21 of the connection component 20N has a first attachment hole 21h with which the fastening member 72 is engaged. The first attachment hole 21h is open in the Z direction. An inner circumferential surface of the first attachment hole 21h of the connection component 20N has a screw groove. The “attachment hole” in the present disclosure may be a screw hole or an insertion hole without a screw groove. The first attachment hole 21h faces the terminal 13 of the electronic component 10N in the Z direction. The fastening member 72 that has passed through the attachment hole 13h of the terminal 13 of the electronic component 10N is engaged with the first attachment hole 21h of the first portion 21, and thus the first portion 21 is physically and electrically connected to the terminal 13 of the electronic component 10N.

A constitution that can be adopted in the connection component 20N of the present embodiment is illustrated in FIG. 17.

### (Second Portion)

The second portion 22 of the connection component 20N is a portion connected to the bus bar 42 (see FIG. 8). The second portion 22 protrudes in the horizontal direction (for example, the X direction) from an end (base end) on the −Z direction side of the first portion 21. The second portion 22 is a plate portion provided in the horizontal direction. The second portion 22 is adjacent (overlaps) to the bus bar 42 in the Z direction, and is connected to the bus bar 42 from the Z direction. A lower surface (a surface on the −Z direction side, including the lower surface of the first portion 21) 22s of the second portion 22 faces an upper surface (a surface on the +Z direction side) 42s of the bus bar 42 in the Z direction. The lower surface 22s of the connection component 20N abuts on the upper surface 42s of the bus bar 42. In this state, the connection component 20N is fixed to the bus bar 42.

The second portion 22 of the connection component 20N is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20N has a third attachment hole 22h through which the fastening member 43 passes. The third attachment hole 22h is open in the Z direction. In the second portion 22, the fastening member 43 that will be described later passes through the third attachment hole 22h. The engagement member 44 (for example, a nut; and see FIG. 3) is engaged with the tip of the fastening member 43 that has passed through the third attachment hole 22h, and thus the second portion 22 is fixed to the bus bar 42.

### (Third Portion)

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as proceeding in the −Z direction.

The third portion 23 may be provided in the connection component 20M described above. On the other hand, the connection component 20N need not have the third portion 23. The third portion 23 can be regarded as a heat dissipation fin 24f.

### <3.2 Connection Component for External Connection>

Next, the connection component 30 for external connection will be described.

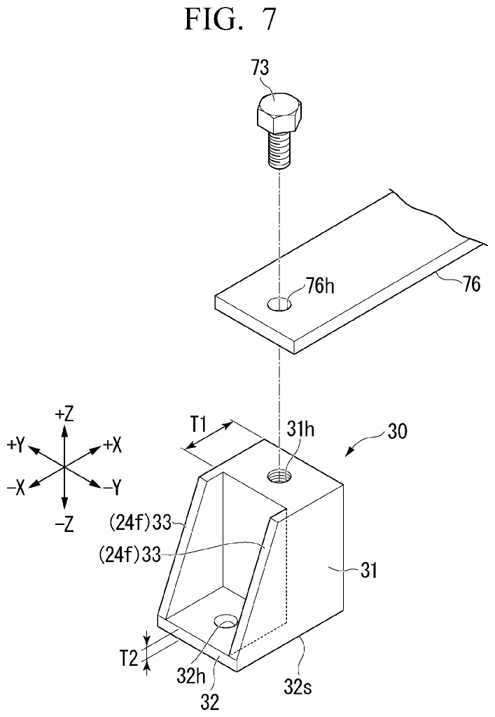

FIG. 7 is a perspective view illustrating the connection component 30 for external connection. The connection component 30 is a component that electrically connects an external connection bus bar 76 to the routing board 40. In the present embodiment, the connection component 30 electrically connects the external connection bus bar 76 to the bus bar 42 (see FIG. 8) included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples. The connection component 30 includes, for example, a first portion 31, a second portion 32, and a third portion 33.

### (First Portion)

The first portion 31 is a portion connected to the external connection bus bar 76. The first portion 31 is a rectangular parallelepiped portion extending in the Z direction. The first portion 31 is a standing portion standing in the Z direction with respect to the routing board 40 (for example, with respect to the bus bar 42). The first portion 31 is adjacent to the external connection bus bar 76 in the Z direction, and is connected to the external connection bus bar 76 from the Z direction. The first portion 31 has a first attachment hole 31h through which a fastening member 73 (for example, a screw or a bolt) passes. The first attachment hole 31h is open in the Z direction. An inner circumferential surface of the first attachment hole 31h has a screw groove. The “attachment hole” in the present disclosure may be a screw hole or an insertion hole without a screw groove. The fastening member 73 that has passed through the attachment hole 76h of the external connection bus bar 76 is engaged with the attachment hole 31h of the first portion 31, and thus the first portion 31 is physically and electrically connected to the external connection bus bar 76.

A constitution that can be adopted in the connection component 30 of the present embodiment is illustrated in FIG. 17.

### (Second Portion)

The second portion 32 is a portion connected to the bus bar 42 (see FIG. 8). The second portion 32 protrudes in the horizontal direction (for example, the X direction) from an end (base end) on the −Z direction side of the first portion 31. The second portion 32 is a plate portion provided in the horizontal direction. The second portion 32 is adjacent (overlaps) to the bus bar 42 in the Z direction, and is connected to the bus bar 42 from the Z direction. A lower surface (a surface on the −Z direction side, including a lower surface of the first portion 31) 32s of the second portion 32 faces the upper surface (the surface on the +Z direction side) 42s of the bus bar 42 in the Z direction. The lower surface 32s of the connection component 30 abuts on the upper surface 42s of the bus bar 42. In this state, the connection component 30 is fixed to the bus bar 42.

The second portion 32 of the connection component 30 is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 32 has a third attachment hole 32h through which the fastening member 43 passes. The third attachment hole 32h is open in the Z direction. In the second portion 32, the fastening member 43 that will be described later passes through the third attachment hole 32h. The engagement member 44 (for example, a nut; and see FIG. 3) is engaged with the tip of the fastening member 43 that has passed through the third attachment hole 32h, and thus the second portion 32 is fixed to the bus bar 42.

### (Third Portion)

The third portion 33 is a standing wall (side wall) standing in the +Z direction from both ends of the second portion 32 in the horizontal direction. The third portion 33 is a wall provided in the Z direction. The third portion 33 is connected to the first portion 31 and is also connected to the second portion 32. For example, the third portion 33 extends obliquely to increase in the X direction (or the Y direction) as proceeding in the −Z direction. The connection component 30 need not include the third portion 33.

### <3.3 Routing Board>

Next, the routing board 40 will be described.

FIG. 8 is a perspective view illustrating the routing board 40. The routing board 40 is a member that forms at least a part of an energization path between the plurality of electronic components 10 and/or at least a part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding. For example, an opening (corresponding to an accommodation portion 55 that will be described later) capable of fixing the bus bar 42 through fitting or the like may be formed in the routing board 40 formed separately from the bus bar 42, and the bus bar 42 may be fixed to the opening to form a bus bar insert plate.

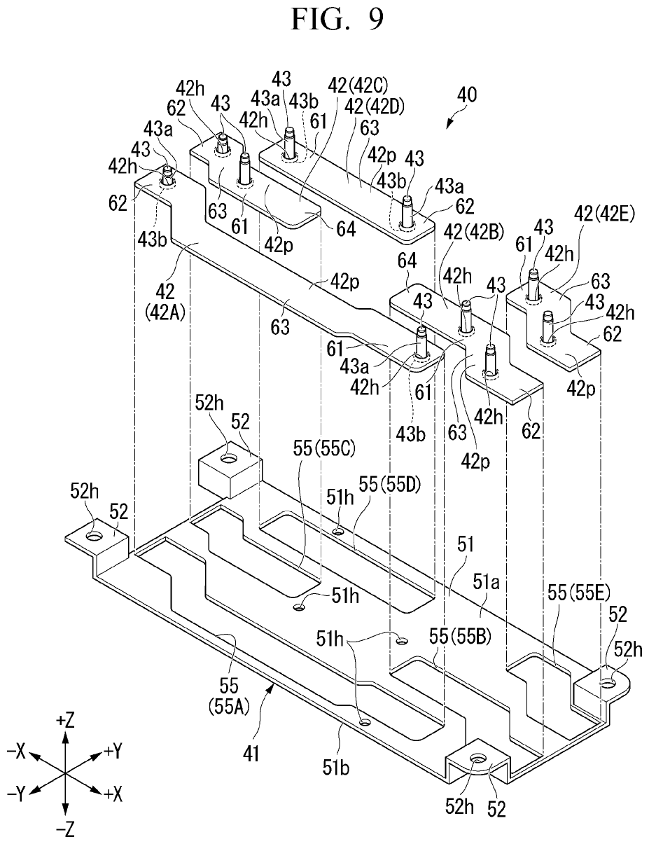

FIG. 9 is a partially exploded perspective view of the routing board 40. Hereinafter, for convenience of description, the base plate 41, the bus bar 42, and the fastening member 43 will be described with reference to the drawings in which the routing board 40 is partially exploded.

### (Base Plate)

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of a “base member”. The base plate 41 may be referred to as an “insulating substrate”. The base plate 41 includes, for example, a flat surface portion 51 and a plurality of fixing portions 52.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). The thickness direction (plate thickness direction) of the flat surface portion 51 is the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where a part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where a part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41).

Each accommodation portion 55 has an outer shape corresponding to the shape of the bus bar 42 to be accommodated when viewed from the Z direction. In the present embodiment, the flat surface portion 51 includes, for example, five accommodation portions 55A, 55B, 55C, 55D, and 55E as the plurality of accommodation portions 55. The accommodation portion 55A is provided to correspond to a bus bar 42A that will be described later, and accommodates the bus bar 42A. The accommodation portion 55B is provided to correspond to a bus bar 42B that will be described later, and accommodates the bus bar 42B. The accommodation portion 55C is provided to correspond to a bus bar 42C that will be described later, and accommodates the bus bar 42C. The accommodation portion 55D is provided to correspond to a bus bar 42D that will be described later, and accommodates the bus bar 42D. The accommodation portion 55E is provided to correspond to a bus bar 42E that will be described later, and accommodates the bus bar 42E.

### (Bus Bar)

The bus bar 42 is a routing member (electrical connection member) included in the routing board 40. The bus bar 42 is, for example, a routing member for electrically connecting the plurality of electronic components 10. Alternatively, the bus bar 42 may be a routing member for connecting the electronic component 10 to an external device. The bus bar 42 is made of a metal (for example, copper or a copper alloy) and has conductivity. In the present embodiment, the routing board 40 includes, for example, five bus bars 42A, 42B, 42C, 42D, and 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E include portions arranged on the same plane. The five bus bars 42A, 42B, 42C, 42D, and 42E are held by the flat surface portion 51 of the base plate 41.

At least a part of each bus bar 42 has a plate shape formed in the horizontal direction. At least a part of each bus bar 42 is accommodated in the accommodation portion 55 and extends along the flat surface portion 51. That is, at least a part of each bus bar 42 extends along the first surface 51a of the flat surface portion 51. At least a part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. Hereinafter, a portion of each bus bar 42 that is accommodated in the accommodation portion 55 and extends along the flat surface portion 51 may be referred to as a “plate portion 42p”. The bus bar 42 is a member that forms a horizontal energization path. The bus bar 42 may be referred to as a “horizontal routing member”.

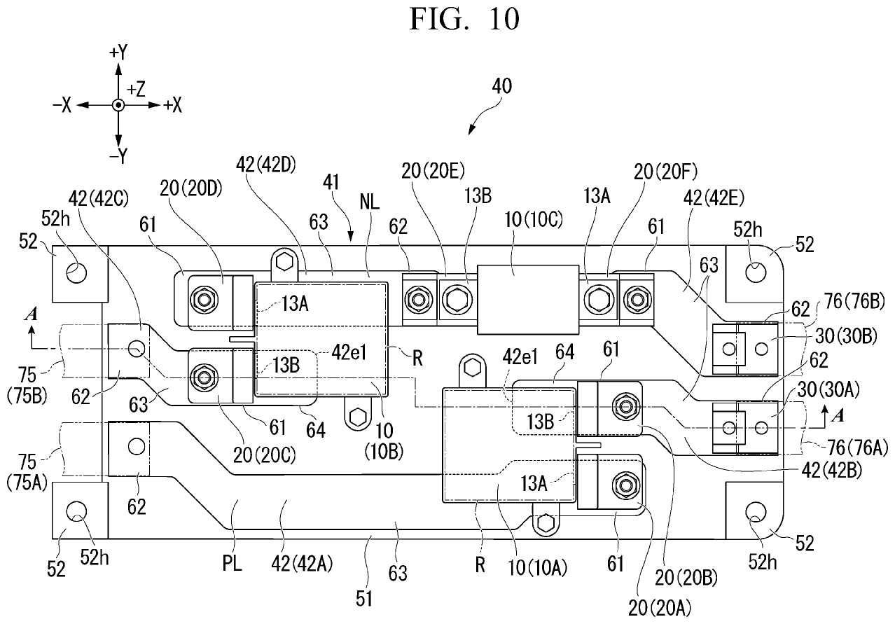

FIG. 10 is a plan view illustrating the routing board 40. The plate portion 42p of each bus bar 42 has, for example, a first connection portion 61, a second connection portion 62, and an extending portion 63.

The first connection portion 61 is a portion in contact with one connection component 20 (hereinafter referred to as a “first connection component 20”). The first connection component 20 is a connection component that connects one electronic component 10 (hereinafter referred to as a “first electronic component 10”) to the bus bar 42. The first connection portion 61 is a portion of the bus bar 42 overlapping the first connection component 20 when viewed from the Z direction. The first connection portion 61 is adjacent to the first connection component 20 in the Z direction, and is connected to the first connection component 20 from the Z direction.

The second connection portion 62 is a portion in contact with another connection component 20 (hereinafter referred to as a “second connection component 20”). The second connection component 20 is a connection component that connects another electronic component 10 (hereinafter referred to as a “second electronic component 10”) included in the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction, and is connected to the second connection component 20 from the Z direction.

Note that the second connection portion 62 may be a portion in contact with another connection component 30 (hereinafter referred to as a “second connection component 30”) instead of the above example. The connection component 30 is a connection component for connecting an external device to the bus bar 42. In this case, the second connection portion 62 is a portion of the bus bar 42 overlapping the second connection component 30 when viewed from the Z direction. The second connection portion 62 is adjacent to the second connection component 30 in the Z direction, and is connected to the second connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction, and is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 is accommodated in the accommodation portion 55 at least over the first connection portion 61 and the second connection portion 62 and extends along the flat surface portion 51. For example, the first connection portion 61, the second connection portion 62, and the extending portion 63 are accommodated in the accommodation portion 55 and extend along the flat surface portion 51.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 has a portion extending linearly in the X direction. This portion extends over the region R overlapping the electronic component 10 when viewed from the Z direction, over the +X direction side and the −X direction side of the region R. That is, the bus bar 42 is accommodated in the accommodation portion 55 to be easily routed through a better path (for example, a path with a shorter distance) without being disturbed by the presence of the electronic component 10.

The one or more bus bars 42 may have an extension 64 in addition to the first connection portion 61, the second connection portion 62, and the extending portion 63. The extension 64 is a portion where the bus bar 42 extends or branches for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

### (Fastening Member)

Next, referring to FIG. 9 again, the fastening member 43 will be described. The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42. The fastening member 43 is an example of a “fastening portion”.

In the present embodiment, each of the first connection portion 61 and the second connection portion 62 of the bus bar 42 has a through-hole 42h. The through-hole 42h penetrates the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a of the fastening member 43 protrudes in the +Z direction from the through-hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 72 or the fastening member 71. For example, in the connection component 20, the shaft 43a of the fastening member 43 is inserted into the third attachment hole 22h of the second portion 22. The engagement member 44 (for example, a nut) is engaged with the shaft 43a of the fastening member 43 protruding from the third attachment hole 22h of the second portion 22 of the connection component 20. The engagement member 44 is attached to the shaft 43a in the Z direction, for example. This engagement fixes the second portion 22 of the connection component 20 to the fastening member 43.

### <4. Metal Plate, Insulating Sheet, Heat Transfer Member, and Insulating Cover>

Next, the metal plate 80, the insulating sheet 91, the heat transfer member 92, and the insulating cover 93 will be described.

### <4.1 Metal Plate>

FIG. 11 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 may be referred to as a “rigid member”. The metal plate 80 is a single metal plate.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. The metal plate 80 includes, for example, a flat surface portion 81, a plurality of fixing portions 82, and a plurality of fixing portions 83.

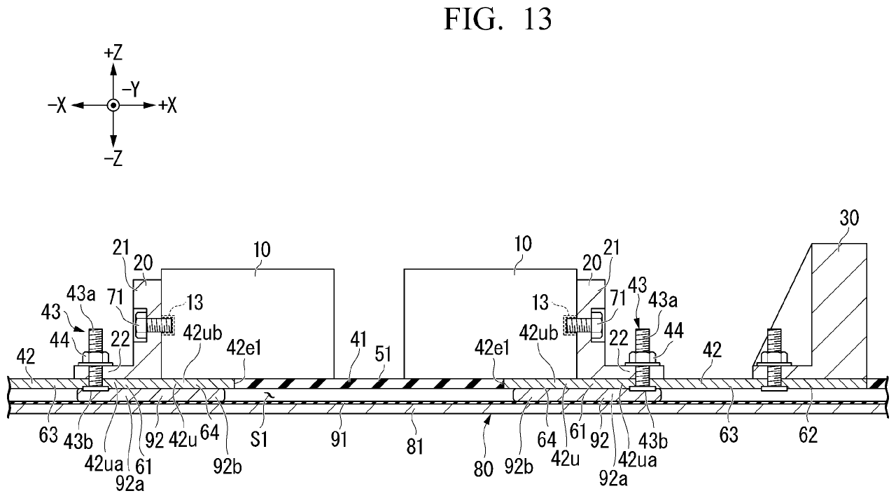

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces the routing boards 40 of the three subunits SU. In the present embodiment, the metal plate 80 forms a gap S1 (see FIG. 13) with the second surface 51b of the flat surface portion 51 of each subunit SU, and faces the second surface 51b of the flat surface portion 51 of each subunit SU.

The fixing portion 82 is a fixing portion for fixing the base plate 41 of each subunit SU to the metal plate 80. The fixing portion 82 is provided at a position corresponding to the fixing portion 52 of the base plate 41 of each subunit SU when viewed from the Z direction. The fixing portion 82 is a cylindrical or prismatic boss protruding in the +Z direction from the flat surface portion 81 of the metal plate 80.

The fixing portion 83 is a fixing portion for directly fixing the electronic component 10 of each subunit SU to the metal plate 80 without interposing the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81.

### <4.2 Insulating Sheet>

The insulating sheet 91 is an insulating member for electrically insulating the metal plate 80 and the bus bars 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding the fixing portion 82 and the fixing portion 83 of the metal plate 80. Note that, instead of the above example, the insulating sheet 91 may be provided between the routing board 40 of each subunit SU and the plurality of heat transfer members 92. Note that, in a case where the heat transfer member 92 has an insulating property and the necessary insulating property is secured by the heat transfer member 92, the insulating sheet 91 may be omitted.

### <4.3 Heat Transfer Member>

The heat transfer member 92 is a member for transferring heat generated by the electronic component 10 at the time of energization and/or heat (Joule heat) generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

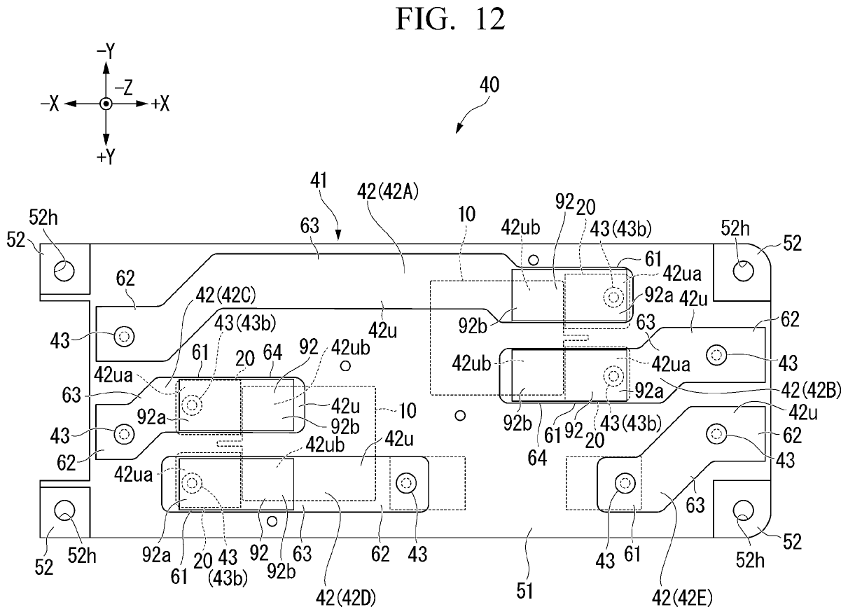

FIG. 12 is a bottom view illustrating the routing board 40. In the present embodiment, the plurality of heat transfer members 92 are partially provided in the routing board 40. For example, the plurality of heat transfer members 92 are disposed at positions overlapping a part of the bus bar 42 when viewed from the Z direction. More specifically, the plurality of heat transfer members 92 are disposed at positions overlapping a part of the bus bar 42 in the vicinity of the electronic component 10 (for example, the electronic components 10A and 10B) when viewed from the Z direction. In the present embodiment, the plurality of heat transfer members 92 are disposed at positions overlapping the connection component 20 when viewed from the Z direction.

FIG. 13 is a cross-sectional view taken along line A-A of the structure illustrated in FIG. 10. In the present embodiment, the heat transfer member 92 is disposed between the metal plate 80 and the bus bar 42. The heat transfer member 92 transfers heat transferred from the electronic component 10 to the bus bar 42 and/or heat generated by the bus bar 42 from the bus bar 42 to the metal plate 80.

In the present embodiment, a part of the heat transfer member 92 is in contact with the bus bar 42 at a position overlapping the connection component 20 when viewed from the Z direction. In this case, the heat transfer member 92 easily transfers the heat transferred from the terminal 13 of the electronic component 10 to the connection component 20 from the connection component 20 to the metal plate 80 via the bus bar 42.

In the present embodiment, a part of the heat transfer member 92 is disposed at a position overlapping the head 43b of the fastening member 43 when viewed from the Z direction, and is in contact with the head 43b of the fastening member 43. In this case, the heat transfer member 92 easily transfers the heat transferred from the terminal 13 of the electronic component 10 to the connection component 20 from the fastening member 43 to the metal plate 80.

In the present embodiment, a part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 13, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### <4.4 Insulating Cover>

Referring to FIG. 1 again, the insulating cover 93 will be described. The insulating cover 93 is a member for preventing the main body MU from contacting the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached to the metal plate 80 in the Z direction. Note that the insulating cover 93 is not limited to a box-shaped member, and may be a sheet-shaped member that covers the energization path of the main body MU.

### <5. Exposure Structure of Bus Bar>

Next, an exposure structure of the bus bar 42 will be described.

### <5.1 Exposure Structure on Upper Surface Side of Bus Bar>

First, an exposure structure on the upper surface side of the bus bar 42 will be described with reference to FIG. 8. In the present embodiment, at least a part of the extending portion 63 of the bus bar 42 is exposed to the outside of the base plate 41 on the upper surface side (the first surface 51a side of the flat surface portion 51). For example, the extending portion 63 of the bus bar 42 is exposed to the outside of the base plate 41 on the upper surface side at least in a part of the region R (see FIG. 10) overlapping the electronic component 10 when viewed from the Z direction.

In the present embodiment, the bus bar 42 is accommodated in the accommodation portion 55 at least over the entire length between the first connection portion 61 and the second connection portion 62 and extends along the first surface 51a of the flat surface portion 51. The bus bar 42 is exposed to the outside of the base plate 41 on the upper surface side at least over the entire length between the first connection portion 61 and the second connection portion 62.

In the present embodiment, the bus bar 42 is accommodated in the accommodation portion 55 over the entire length of the bus bar 42 and extends along the first surface 51a of the flat surface portion 51. The bus bar 42 is exposed to the outside of the base plate 41 on the upper surface side over the entire length of the bus bar 42.

As illustrated in FIG. 13, at least a part of the extending portion 63 of the bus bar 42 is exposed to the outside of the base plate 41 not only on the upper surface side but also on the lower surface side (second surface 51b side). For example, the bus bar 42 is exposed to the outside of the base plate 41 on the lower surface side over the entire length of the bus bar 42.

### <5.2 Exposure Structure on Lower Surface Side of Bus Bar>

Next, an exposure structure on the lower surface side of the bus bar 42 will be described with reference to FIG. 13. In the present embodiment, the plate portion 42p of the bus bar 42 includes an exposed portion 42u exposed to the outside of the base plate 41 on the lower surface side (the second surface 51b side of the flat surface portion 51). In the present embodiment, the exposed portion 42u of the bus bar 42 extends over the entire length of the bus bar 42. In the present embodiment, the heat transfer member 92 is disposed between the exposed portion 42u of the bus bar 42 and the metal plate 80. For example, the heat transfer member 92 is in contact with the exposed portion 42u of the bus bar 42.

In the present embodiment, at least a part of the exposed portion 42u of the bus bar 42 is provided in a region overlapping the connection component 20 when viewed from the Z direction. At least a part of the heat transfer member 92 overlaps the exposed portion 42u of the bus bar 42 in a region overlapping the connection component 20 when viewed from the Z direction. For example, at least a part of the heat transfer member 92 is in contact with the exposed portion 42u of the bus bar 42 in a region overlapping the connection component 20 when viewed from the Z direction.

In the present embodiment, the exposed portion 42u of the bus bar 42 includes a first portion 42ua disposed in a region overlapping the connection component 20 when viewed from the Z direction and a second portion 42ub disposed in a region overlapping the electronic component 10 when viewed from the Z direction.

The heat transfer member 92 includes a first heat transfer portion 92a and a second heat transfer portion 92b. The first heat transfer portion 92a overlaps the first portion 42ua of the exposed portion 42u of the bus bar 42 in a region overlapping the connection component 20 when viewed from the Z direction. For example, the first heat transfer portion 92a is in contact with the first portion 42ua of the exposed portion 42u of the bus bar 42. On the other hand, the second heat transfer portion 92b overlaps the second portion 42ub of the exposed portion 42u of the bus bar 42 in a region overlapping the electronic component 10 when viewed from the Z direction. For example, the second heat transfer portion 92b is in contact with the second portion 42ub of the exposed portion 42u of the bus bar 42.

As described above, at least a part of the extending portion 63 of the bus bar 42 is exposed to the outside of the base plate 41 not only on the lower surface side but also on the upper surface side (first surface 51a side). For example, the bus bar 42 is exposed to the outside of the base plate 41 on the upper surface side over the entire length of the bus bar 42. For example, the second portion 42ub of the exposed portion 42u of the bus bar 42 is exposed to the outside of the base plate 41 not only on the lower surface side but also on the upper surface side, and faces the electronic component 10.

### <6. Three-Dimensional Routing Structure of Bus Bar>

Next, a three-dimensional routing structure CS of the bus bar 42 will be described.

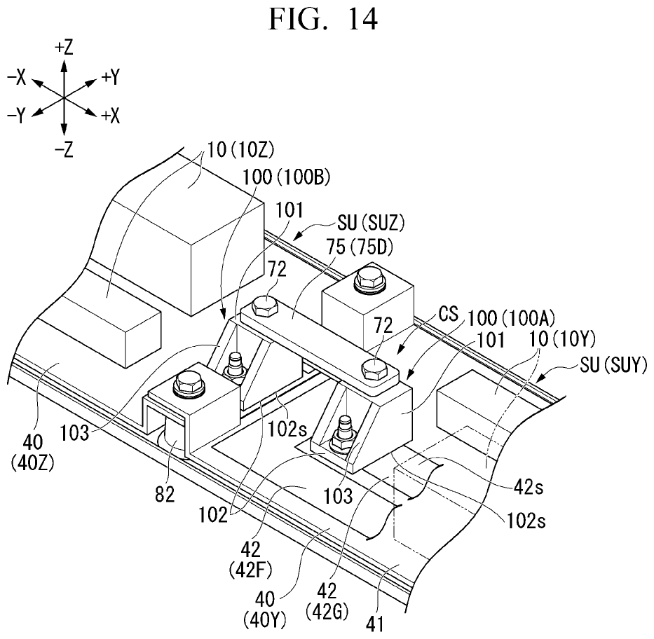

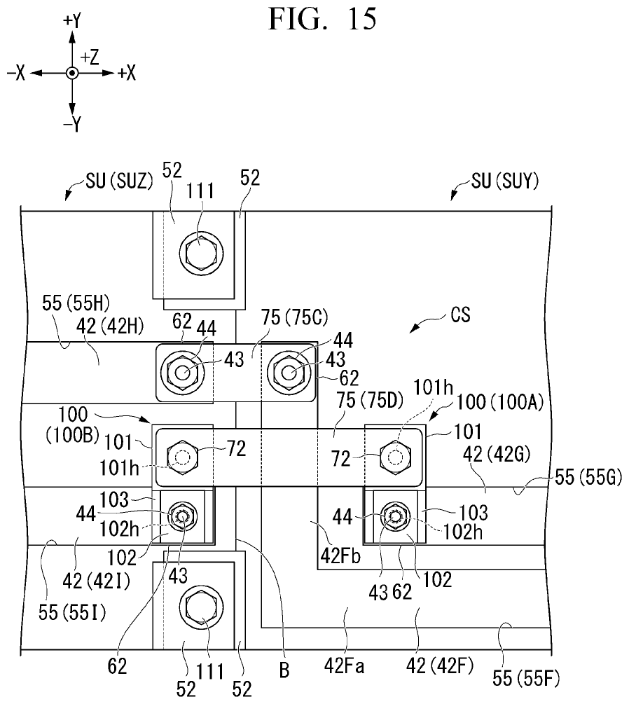

FIG. 14 is a perspective view illustrating the three-dimensional routing structure CS of the bus bar 42. FIG. 15 is a plan view illustrating the three-dimensional routing structure CS of the bus bar 42. The three-dimensional routing structure CS includes a bus bar 42F, a bus bar 42G, a bus bar 42H, and a bus bar 42I as the plurality of bus bars 42. In addition, the three-dimensional routing structure CS includes a plurality of connection components 100. The three-dimensional routing structure CS includes a coupling bus bar 75C and a coupling bus bar 75D as the plurality of coupling bus bars 75.

The bus bar 42F and the bus bar 42G are, for example, the bus bars 42 included in the subunit SUY. The flat surface portion 51 of the base plate 41 of the subunit SUY includes an accommodation portion 55F and an accommodation portion 55G as the plurality of accommodation portions 55. The bus bar 42F is accommodated in the accommodation portion 55F and extends along the flat surface portion 51. The bus bar 42G is accommodated in the accommodation portion 55G and extends along the flat surface portion 51. The bus bar 42F is an example of a “first bus bar”. The accommodation portion 55F that accommodates the bus bar 42F is an example of a “first accommodation portion”. The bus bar 42G is an example of a “fourth bus bar”. The accommodation portion 55G that accommodates the bus bar 42G is an example of a “fourth accommodation portion”. The bus bar 42F and the bus bar 42G are the bus bars 42 located in the first layer (lower layer) in the three-dimensional routing structure CS.

In the present embodiment, the bus bar 42F includes a first portion 42Fa extending in the X direction and a second portion 42Fb bent from the first portion 42Fa and extending in the Y direction. The second portion 42Fb extends along a boundary B between the subunit SUY and the subunit SUZ.

On the other hand, the bus bar 42H and the bus bar 42I are, for example, the bus bars 42 included in the subunit SUZ. The flat surface portion 51 of the base plate 41 of the subunit SUZ includes an accommodation portion 55H and an accommodation portion 55I as the plurality of accommodation portions 55. The bus bar 42H is accommodated in the accommodation portion 55H and extends along the flat surface portion 51. The bus bar 42I is accommodated in the accommodation portion 55I and extends along the flat surface portion 51. The bus bar 42H and the bus bar 42I are the bus bars 42 located in the first layer (lower layer) in the three-dimensional routing structure CS.

The connection component 100 has the same constitution as the connection component 30 for external connection described above. For example, the connection component 100 has a first portion 101, a second portion 102, and a third portion 103. For details of the connection component 100, in the above description regarding the connection component 30, the “connection component 30” may be replaced with the “connection component 100”, the “first portion 31” may be replaced with the “first portion 101”, the “first attachment hole 31h” may be replaced with the “first attachment hole 101h”, the “second portion 32” may be replaced with the “second portion 102”, the “third attachment hole 32h” may be replaced with the “third attachment hole 102h”, and the “third portion 33” may be replaced with the “third portion 103”. The connection component 100 is a member forming an energization path in the vertical direction. The connection component 100 may be referred to as a “vertical routing member”. The reference number 102s in FIG. 14 denotes a lower surface (including a lower surface of the first portion 101) of the second portion 102 of the connection component 100. The lower surface 102s faces the upper surface 42s of the bus bar 42 in the Z direction.

The plurality of connection components 100 include a connection component 100A and a connection component 100B. The connection component 100A overlaps the second connection portion 62 of the bus bar 42G in the subunit SUY when viewed from the Z direction. The connection component 100A is adjacent to the second connection portion 62 of the bus bar 42G in the Z direction, and is connected to the second connection portion 62 of the bus bar 42G from the Z direction. The connection component 100A stands in the +Z direction from the bus bar 42G.

The connection component 100B overlaps the second connection portion 62 of the bus bar 42I in the subunit SUZ when viewed from the Z direction. The connection component 100B is adjacent to the second connection portion 62 of the bus bar 42I in the Z direction, and is connected to the second connection portion 62 of the bus bar 42I from the Z direction. The connection component 100B stands in the +Z direction from the bus bar 42I.

One end of the coupling bus bar 75C is adjacent to the second connection portion 62 of the bus bar 42F in the Z direction and is connected to the second connection portion 62 of the bus bar 42F from the Z direction in the subunit SUY. The other end of the coupling bus bar 75C is adjacent to the second connection portion 62 of the bus bar 42H in the Z direction and is connected to the second connection portion 62 of the bus bar 42H from the Z direction in the subunit SUZ. With this constitution, the bus bar 42F of the subunit SUY and the bus bar 42H of the subunit SUZ are electrically connected via the coupling bus bar 75C. The coupling bus bar 75C is the bus bar 75 located in the first layer (lower layer) in the three-dimensional routing structure CS.

On the other hand, in the subunit SUY, the coupling bus bar 75D is adjacent to the first portion 101 of the connection component 100A in the Z direction, and is connected to the first portion 101 of the connection component 100A from the Z direction. The other end of the coupling bus bar 75D is adjacent to the first portion 101 of the connection component 100B in the Z direction in the subunit SUZ, and is connected to the first portion 101 of the connection component 100B from the Z direction.

The coupling bus bar 75D is supported by the first portion 101 of the connection component 100A and the first portion 101 of the connection component 100B at a position away from the bus bar 42F in the Z direction. The coupling bus bar 75D is supported by the first portion 101 of the connection component 100A and the first portion 101 of the connection component 100B, and extends in the horizontal direction (for example, the X direction). The coupling bus bar 75D is electrically connected to the first portion 101 of the connection component 100A and the first portion 101 of the connection component 100B. With this constitution, the bus bar 42F of the subunit SUY and the bus bar 42I of the subunit SUZ are electrically connected via the two connection components 100 and the coupling bus bar 75D.

In the present embodiment, the coupling bus bar 75D extends to straddle the second portion 42Fb of the bus bar 42F at a position away from the bus bar 42F in the +Z direction. As a result, a three-dimensional intersecting structure is formed by the coupling bus bar 75D and the bus bar 42F. In the present embodiment, the coupling bus bar 75D extends to straddle the boundary B of the plurality of subunits SU.

In the present embodiment, the three-dimensional routing structure CS of the bus bar 42 is provided at a position of straddling the boundary B of the plurality of subunits SU. According to such a disposition, the coupling structure between the plurality of subunits SU is reinforced by the three-dimensional routing structure CS. Note that the three-dimensional routing structure CS of the bus bar 42 may be provided inside one or more subunits SU instead of being provided at the boundary B of the plurality of subunits SU.

### <12. Structure Related to Connection Component>

Next, a structure related to the connection component 20 will be described.

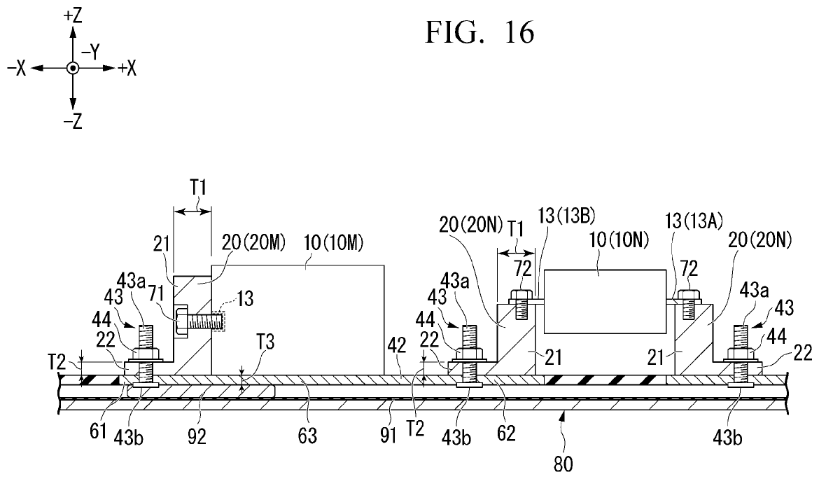

FIG. 16 is a cross-sectional view for describing a structure related to the connection component 20. In the present embodiment, the connection components 20 (for example, the connection component 20M and the connection component 20N) are heat storage members (heat absorbing members) that increase the heat capacity of the energization path of the electrical connection unit 1. The connection component 20 stores (absorbs) at least a part of heat generated by the electronic component 10, for example. Alternatively/additionally, the connection component 20 may store (absorb) at least a part of heat generated by the bus bar 42 itself due to energization. The connection component 20 may be referred to as a “heat storage component” or a “heat absorbing component”.

In the present embodiment, the bus bar 42 is disposed at a position away from the terminal 13 of the electronic component 10 (for example, a position away in the Z direction). The connection component 20 is disposed between the electronic component 10 and the bus bar 42. In the present disclosure, the phrase “the connection component is disposed between the electronic component and the bus bar” is not limited to a case where a part of the connection component is located between the electronic component and the bus bar when viewed from the X direction or the Y direction. The phrase “the connection component is disposed between the electronic component and the bus bar” may correspond to a case where a part of the connection component is located between the electronic component and the bus bar when viewed from a direction inclined with respect to the X direction or the Y direction. The connection component 20 electrically connects the terminal 13 of the electronic component 10 to the bus bar 42.

In the present embodiment, a thickness of at least a part of the connection component 20 is larger than a plate thickness (a thickness in the Z direction) T3 of the bus bar 42. For example, a thickness T1 of at least a part of the connection component 20 in the X direction is larger than the plate thickness T3 of the bus bar 42. In the present embodiment, the thickness T1 of the first portion 21 of the connection component 20 in the X direction is larger than the plate thickness T3 of the bus bar 42. In the present embodiment, the first portion 21 has the thickness T1 larger than the plate thickness T3 of the bus bar 42 as a thickness in the X direction over the entire length of the first portion 21 in the Z direction. The thickness T1 of the first portion 21 of the connection component 20 in the X direction is, for example, twice or more the plate thickness T3 of the bus bar 42. From another point of view, a thickness T2 of the second portion 22 of the connection component 20 in the Z direction may be larger than the plate thickness T3 of the bus bar 42.

In the present embodiment, the thickness T1 of the first portion 21 of the connection component 20 in the X direction is larger than the thickness T2 of the second portion 22 of the connection component 20 in the Z direction. In the present embodiment, the first portion 21 has the thickness T1 larger than the thickness T2 of the second portion 22 in the Z direction as a thickness in the X direction over the entire length of the first portion 21 in the Z direction. As a result, as illustrated in FIG. 17, the first attachment hole 21hA is easily formed within the thickness T1 of the first portion 21, and the heat storage capacity of the first portion 21 and the connection component 20 is increased.

The dimensional relationship described above is the same for the connection component 30 to which the external connection bus bar 76 is connected and/or the connection component 100 to which the coupling bus bar 75 is connected. For example, in the description of the connection component 30, the “connection component 20” may be replaced with the “connection component 30” , the “first portion 21” may be replaced with the “first portion 31”, and the “second portion 22” may be replaced with the “second portion 32” in the description of the connection component 20. Similarly, in the description of the connection component 100, the “connection component 20” may be replaced with the “connection component 100”, the “first portion 21” may be replaced with the “first portion 101”, and the “second portion 22” may be replaced with the “second portion 102” in the description of the connection component 20.

### <14. Advantages of Present Embodiment>

### <A. Advantages of Routing Board>

As a comparative example, an electrical connection unit in which a bus bar is disposed in a standing posture with respect to a lower wall of a housing will be considered. In such a constitution of the comparative example, it may be difficult to reduce the height of the electrical connection unit due to a width of the standing bus bar.

On the other hand, in the present embodiment, the electrical connection unit 1 includes the first electronic component 10 and the routing board 40. The routing board 40 includes the base plate 41 and the first bus bar 42. The base plate 41 has the plate-shaped flat surface portion 51 having a first surface 51a facing the first electronic component 10. The flat surface portion 51 has the first accommodation portion 55 recessed in the Z direction or penetrating the flat surface portion 51 in the Z direction. At least a part of the first bus bar 42 is accommodated in the first accommodation portion 55 and extends along the flat surface portion 51. According to such a constitution, compared with the structure of the comparative example in which at least a part of the routing path is formed on a plane, the bus bar is less likely to be affected in the height direction, and the height of the electrical connection unit 1 can be easily reduced.

In the present embodiment, the electrical connection unit 1 has the first connection component 20. The first connection component 20 includes a portion standing with respect to the first bus bar 42, and electrically connects the first electronic component 10 to the first bus bar 42. The first bus bar 42 has the first connection portion 61 in contact with the first connection component 20. The first connection portion 61 is accommodated in the first accommodation portion 55 and extends along the flat surface portion 51. According to such a constitution, since more portions of the routing path are formed on a plane, it is further easy to reduce the height of the electrical connection unit 1.

In the present embodiment, the electrical connection unit 1 has the second connection component 20. The second connection component 20 includes a portion standing with respect to the first bus bar 42, and electrically connects the second electronic component or an external device to the first bus bar 42. The first bus bar 42 has a second connection portion 62 in contact with the second connection component 20. The first bus bar 42 is accommodated in the first accommodation portion 55 at least over the first connection portion 61 and the second connection portion 62 and extends along the flat surface portion 51. According to such a constitution, since more portions of the routing path are formed on a plane, it is further easy to reduce the height of the electrical connection unit 1.

In the present embodiment, the first bus bar 42 has the extending portion 63 between the first connection portion 61 and the second connection portion 62. The extending portion 63 is accommodated in the first accommodation portion 55, passes through the region R overlapping the electronic component 10 when viewed from the Z direction, and extends over both sides of the region R. According to such a constitution, since the extending portion 63 is accommodated in the first accommodation portion 55, it is difficult to be restricted in the routing layout due to the presence of the electronic component 10. Thus, for example, it is possible to achieve a routing layout that makes electrical characteristics more advantageous, such as making it easier to cause the extending portion 63 to linearly extend. In addition, routing of the bus bar around the electronic component 10 can be avoided. This makes it possible to improve the electrical characteristics of the electrical connection unit 1 and/or to reduce the size of the electrical connection unit 1.

In the present embodiment, the first bus bar 42 extends to the region R overlapping the first electronic component 10 when viewed from the Z direction, and has the extension 64 having the end 42e1 at a position overlapping the first electronic component 10. The extension 64 is accommodated in the first accommodation portion 55 and extends along the flat surface portion 51. According to this constitution, since the extension 64 is accommodated in the first accommodation portion 55, the height of the electrical connection unit 1 can be reduced, and a metallic heat dissipation portion (extension 64) for promoting heat dissipation and/or heat storage of the first electronic component 10 can be disposed below the first electronic component 10. As a result, it is possible to improve the heat dissipation property and/or the heat storage property of the electrical connection unit 1.

In the present embodiment, the first bus bar 42 is accommodated in the first accommodation portion 55 over the entire length of the first bus bar 42 and extends along the flat surface portion 51. According to such a constitution, since more portions of the routing path are formed on a plane, it is further easy to reduce the height of the electrical connection unit 1.

In the present embodiment, the electrical connection unit 1 includes the second bus bar 42 electrically connected to the second terminal 13B of the first electronic component 10. The flat surface portion 51 has the second accommodation portion 55 recessed in the Z direction or penetrating the flat surface portion 51 in the Z direction at a position away from the first accommodation portion 55. At least a part of the second bus bar 42 is accommodated in the second accommodation portion 55 and extends along the flat surface portion 51. According to such a constitution, since more portions of the routing path including the plurality of bus bars 42 are held on a plane by one base plate 41, it becomes easier to reduce the height of the electrical connection unit 1.

In the present embodiment, the electrical connection unit 1 includes the third bus bar 42. The first bus bar 42 is a bus bar included in the positive electrode line PL. The third bus bar 42 is a bus bar included in the negative electrode line NL. The flat surface portion 51 has the third accommodation portion 55 recessed in the Z direction or penetrating the flat surface portion 51 in the Z direction at a position away from the first accommodation portion 55. At least a part of the third bus bar 42 is accommodated in the third accommodation portion 55 and extends along the flat surface portion 51. According to such a constitution, since more portions of the routing path forming the positive electrode line PL and the negative electrode line NL are held on a plane by one base plate 41, it becomes easier to reduce the height of the electrical connection unit 1.

In the present embodiment, the electrical connection unit 1 includes the fourth bus bar 42, the fifth bus bar 42, and the third connection component 100 that electrically connects the fourth bus bar 42 to the fifth bus bar 42. The flat surface portion 51 has the fourth accommodation portion 55 recessed in the Z direction or penetrating the flat surface portion 51 in the Z direction at a position away from the first accommodation portion 55. At least a part of the fourth bus bar 42 is accommodated in the fourth accommodation portion 55 and extends along the flat surface portion 51. The third connection component 100 includes a portion standing with respect to the fourth bus bar 42. The fifth bus bar 42 is supported by the third connection component 100 at a position away from the first bus bar 42 in the Z direction, and extends in parallel with the first surface 51a. According to such a constitution, a routing path in a three-dimensional way can be easily formed by the fourth bus bar 42, the third connection component 100, and the fifth bus bar 42. Thus, the electrical connection unit 1 having excellent assemblability can be provided. In addition, since the fourth bus bar 42 is disposed in the accommodation portion 55 of the base plate 41, a part of the three-dimensional routing path is formed within the thickness of the base plate 41. As a result, it becomes easier to reduce the height of the electrical connection unit 1.

In the present embodiment, the fifth bus bar 42 extends to straddle the first bus bar 42 at a position away from the first bus bar 42 in the Z direction. According to such a constitution, it is easy to form a routing path that three-dimensionally intersects the first bus bar 42 by using the third connection component 100 and the fifth bus bar 42. Thus, the electrical connection unit 1 having excellent assemblability can be provided.

### <B. Advantages of Flat Bus Bars>

As a comparative example, an electrical connection unit in which a bus bar is disposed in a standing posture with respect to a lower wall of a housing will be considered. In such a constitution of the comparative example, it is necessary to fix the bus bar to the housing in a standing posture, and it is difficult to improve workability regarding attachment of the bus bar. In this case, it may be difficult to improve the assemblability of the electrical connection unit 1.

On the other hand, in the present embodiment, the electrical connection unit 1 includes the base plate 41 and the bus bar 42. The base plate 41 includes the flat surface portion 51 having a plate shape. The flat surface portion 51 has the first accommodation portion 55 recessed in the Z direction or penetrating the flat surface portion 51 in the Z direction. At least a part of the bus bar 42 is accommodated in the first accommodation portion 55 and extends along the flat surface portion 51. According to such a constitution, the base plate 41 and the bus bar 42 can be easily handled integrally, and workability regarding attachment of the bus bar can be improved compared with the constitution of the comparative example. Thus, the assemblability of the electrical connection unit 1 can be improved.

In the present embodiment, the bus bar 42 is accommodated in the accommodation portion 55 over the entire length of the bus bar 42 and extends along the flat surface portion 51. According to such a constitution, it is easy to reduce the height of the electrical connection unit 1 while improving the assemblability of the electrical connection unit 1.

In the present embodiment, the bus bar 42 is integrated with the base plate 41 through insert molding. According to such a constitution, it is possible to eliminate or reduce the work of manually attaching the bus bar 42 to the housing. Thus, the assemblability of the electrical connection unit 1 can be further improved.

In the present embodiment, the fastening member 43 protruding from the bus bar 42 in the Z direction and the connection components 20 and 30 attached to the fastening member 43 from the Z direction are provided. The connection components 20 and 30 electrically connect the electronic component 10 or an external device to the bus bar 42. According to such a constitution, a direction of work of attaching a connection target component to the bus bar 42 can be easily aligned with the Z direction. In a case where the direction of work can be aligned, the assemblability of the electrical connection unit 1 can be further improved.

In the present embodiment, the connection component 20 is connected to the electronic component 10 from the X direction (or the Y direction). According to such a constitution, a connection direction of the electronic component 10 with respect to the bus bar 42 can be converted into the Z direction by using the connection component 20 for the electronic component 10 that needs to be connected from the X direction. Thus, the assemblability of the electrical connection unit 1 can be further improved.

### <C. Advantages of Exposure Structure on Upper Surface Side of Bus Bar>

As a comparative example, an electrical connection unit in which the upper surface side of the bus bar 42 is covered with a synthetic resin will be considered. In such a constitution of the comparative example, it is difficult to improve the heat dissipation property of the bus bar 42.

On the other hand, in the present embodiment, the electrical connection unit 1 includes the first electronic component 10 and the routing board 40. The routing board 40 includes a base plate 41 and a bus bar 42. The base plate 41 has the plate-shaped flat surface portion 51 having the first surface 51a facing the first electronic component 10 and the second surface 51b located on the side opposite to the first surface 51a. The flat surface portion 51 has the accommodation portion 55 recessed in the Z direction or penetrating the flat surface portion 51 in the Z direction. At least a part of the bus bar 42 has the plate portion 42p that is accommodated in the accommodation portion 55 and extends along the flat surface portion 51. The plate portion 42p includes the first connection portion 61 overlapping the first connection component 20 when viewed in the Z direction, and the extending portion 63 extending from the first connection portion 61 in a direction intersecting the Z direction. At least a part of the extending portion 63 is exposed to the outside of the base plate 41 on the first surface 51a side. According to such a constitution, at least a part of a portion of the bus bar 42 other than the connection portions 61 and 62 connected to other components is exposed to the outside and functions as an area for releasing heat. In this case, the heat dissipation property of the electrical connection unit 1 can be improved.

In the present embodiment, the extending portion 63 is exposed to the outside of the base plate 41 on the first surface 51a side at least in a part of the region R overlapping the first connection component 20 when viewed from the Z direction. According to such a constitution, it is easy for a part of the extending portion 63 to function as a heat dissipation portion that transfers heat from the first connection component 20. In this case, the heat dissipation property of the electrical connection unit 1 can be improved.

In the present embodiment, the first bus bar 42 has the second connection portion 62 overlapping the second connection components 20 and 30 when viewed in the Z direction. The first bus bar 42 is accommodated in the accommodation portion 55 at least over the entire length between the first connection portion 61 and the second connection portion 62, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

In the present embodiment, the bus bar 42 is accommodated in the accommodation portion 55 over the entire length of the bus bar 42, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

At least a part of the extending portion 63 is exposed to the outside of the base plate 41 not only on the first surface 51a side but also on the second surface 51b side. According to such a constitution, since the wider portion functions as a heat dissipation area, the heat dissipation property of the electrical connection unit 1 can be further improved.

In the modification example of the present embodiment, the electrical connection unit 1 includes the metal plate 80 facing the flat surface portion 51 with the gap S1 between the metal plate 80 and the flat surface portion 51, and the heat transfer member 92 disposed between the bus bar 42 and the metal plate 80. The base plate 41 includes a cover portion 51v that covers at least a part of the extending portion 63 on the second surface 51b side. According to such a constitution, even in a case where heat is likely to be confined in the gap S1 between the base plate 41 and the metal plate 80, it is possible to suppress the heat from being easily confined in the gap S1 by providing the cover portion 51v.

### <D. Advantages of Exposure Structure on Lower Surface Side of Bus Bar>

In order to improve the holding property of the bus bar 42, a structure in which a portion other than the connection surface of the bus bar 42 with the electronic component 10 and the like is covered with a resin may be adopted. However, in the structure in which the portion other than the connection surface of the bus bar 42 is covered, there is a problem that the heat dissipation property of the bus bar 42 deteriorates. In the present embodiment, the lower surface (a surface opposite to the component mounting surface) of the bus bar 42 is exposed, and the heat transfer sheet is set on this exposed surface. The heat transfer sheet is connected to the metal plate 80 (a rigid member or a heat dissipation member) provided below the routing board 40. As a result, heat can be favorably transferred from the bus bar 42 to the metal plate 80 (to the side opposite to the component mounting surface) via the heat transfer sheet.

### <E. Advantages of Constitution of Connection Component>

The connection components 20, 30, and 100 of the present embodiment are connection components that connect the first bus bar 42 to connection target components (the electronic component 10 and the second bus bars 75 and 76), and include the first portions 21, 31, and 101 extending in a first direction (Z direction), and the second portions 22, 32, and 102 extending in a second direction (X direction) intersecting the first direction from one ends of the first portions 21, 31, and 101, facing the first bus bar 42 in the first direction, and fixed to the first bus bar 42.

The first portions 21, 31, and 101 may include a first attachment portion 21fA to which the fastening members 72 and 73 can be attached in the first direction in a case where the first connection target components 10N, 75, and 76 are applied as the connection target components. The first portions 21, 31, and 101 may include a second attachment portion 21fB to which the fastening member 71 is attachable in the second direction in a case where the second connection target component 10M is applied as the connection target component.

According to this constitution, the connection component disposed between the first bus bar 42 and the connection target components 10, 75, and 76 has an L shape having portions extending in the first direction and the second direction intersecting with each other. The first portions 21, 31, and 101 rising in the first direction, which is a direction of facing the first bus bar 42, may include a first attachment portion 21fA to which the first target component can be attached via the fastening members 72 and 73 in the first direction, and a second attachment portion 21fB to which the second target component can be attached via the fastening member 71 in the second direction. As a result, the first target component that needs to be fastened from the direction of facing the first bus bar 42 and the second target component that needs to be fastened from the direction along the first bus bar 42 can be attached to the first bus bar 42 via one type of connection component. Thus, the constitution components of the electrical connection unit 1 can be made common.

In the connection components 20, 30, and 100 of the present embodiment, the first attachment portion 21fA has a first attachment hole 21hA penetrating the first portion in the first direction, and the second attachment portion 21fB has a second attachment hole 21hB penetrating the first portion in the second direction.

According to this constitution, since the attachment holes 21hA and 21hB are through-holes, the attachment portions 21fA and 21fB can be easily formed, and the weight of a connection component can be reduced.

In the connection components 20, 30, and 100 of the present embodiment, the thickness T1 of the first portions 21, 31, and 101 in the second direction is larger than the thickness T2 of the second portions 22, 32, and 102 in the first direction.

According to this constitution, by making the first portions 21, 31, and 101 thicker than the second portions 22, 32, and 102, even in a case where the attachment portions 21fA and 21fB in two directions orthogonal to each other are formed in the first portions 21, 31, and 101, it is possible to easily form the attachment portions, increase the heat storage capacity of the first portions 21, 31, and 101 and the entire connection component, and improve the thermal characteristics of the electrical connection unit 1.

In the connection components 20, 30, and 100 of the present embodiment, when a direction intersecting the first direction and the second direction is a third direction (Y direction), the first attachment portion 21fA and the second attachment portion 21fB are disposed at different positions in the third direction.

According to this constitution, even in a case where the attachment portions 21fA and 21fB in two directions are formed, the first attachment portion 21fA and the second attachment portion 21fB in the first portions 21, 31, and 101 are disposed to be shifted from each other in the third direction intersecting the first direction and the second direction, so that it is easy to increase the interval between the attachment portions 21fA and 21fB in two directions orthogonal to each other in the first portion. Thus, the attachment portions 21fA and 21fB can be easily formed, and the fastening members used for the attachment portions 21fA and 21fB can be separated from each other to facilitate the fastening work.

Further, in the connection components 20, 30, and 100 of the present embodiment, the second portions 22, 32, and 102 have the third attachment portion 22fA fixed to the first bus bar 42 when the fastening member 43 is attached thereto in the first direction.

According to this constitution, since the second portions 22, 32, and 102 have the third attachment portion 22fA fixed to the first bus bar 42, the second portions 22, 32, and 102 separated from the first portions 21, 31, and 101 having the plurality of attachment portions can be fixed to the first bus bar 42.

In the connection components 20, 30, and 100 of the present embodiment, when a direction intersecting the first direction and the second direction is a third direction (Y direction), the first attachment portion 21fA, the second attachment portion 21fB, and the third attachment portion 22fA are disposed at different positions in the third direction.

According to this constitution, since the three attachment portions are disposed to be shifted from each other, the fastening members used for the attachment portions can be separated from each other to facilitate the fastening work.

In the connection components 20, 30, and 100 of the present embodiment, the connection target component is the electronic component 10 or the second bus bars 75 and 76.

According to this constitution, a plurality of types of connection target components can be attached to the first bus bar 42 via one type of connection component, so that constitution components of the electrical connection unit 1 can be made common.

Since the electrical connection unit 1 of the present embodiment includes the first bus bar 42 and the connection components 20, 30, and 100, the first target component that needs to be fastened from the direction of facing the first bus bar 42 and the second target component that needs to be fastened from the direction along the first bus bar 42 can be attached to the first bus bar 42 via one type of connection component, and thus constitution components can be made common.

### <Fixing Structure of Connection Component>

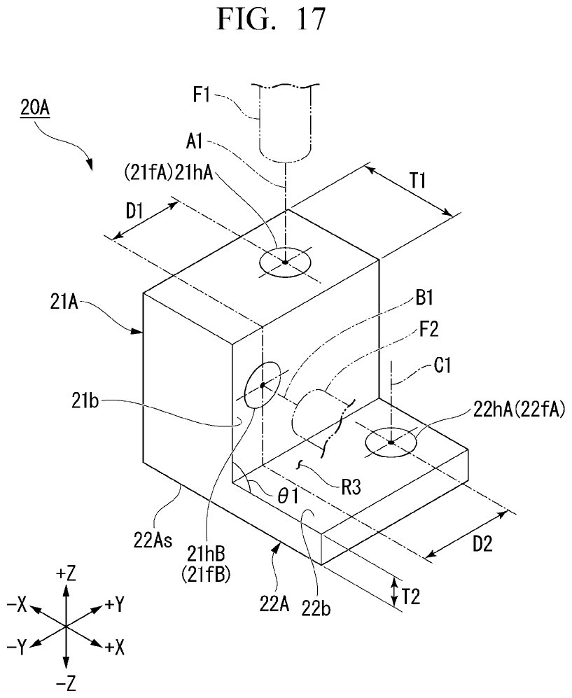

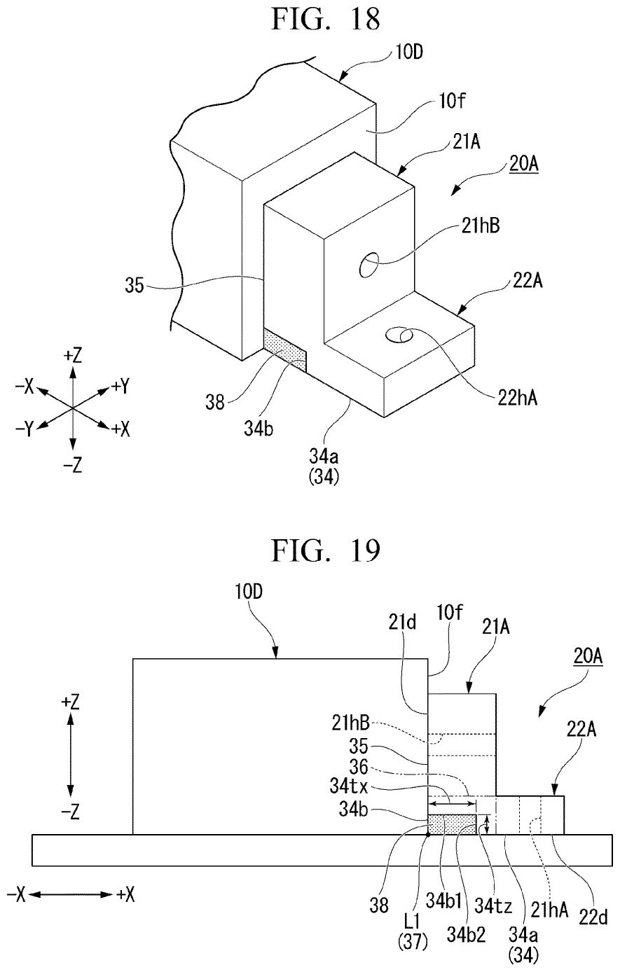

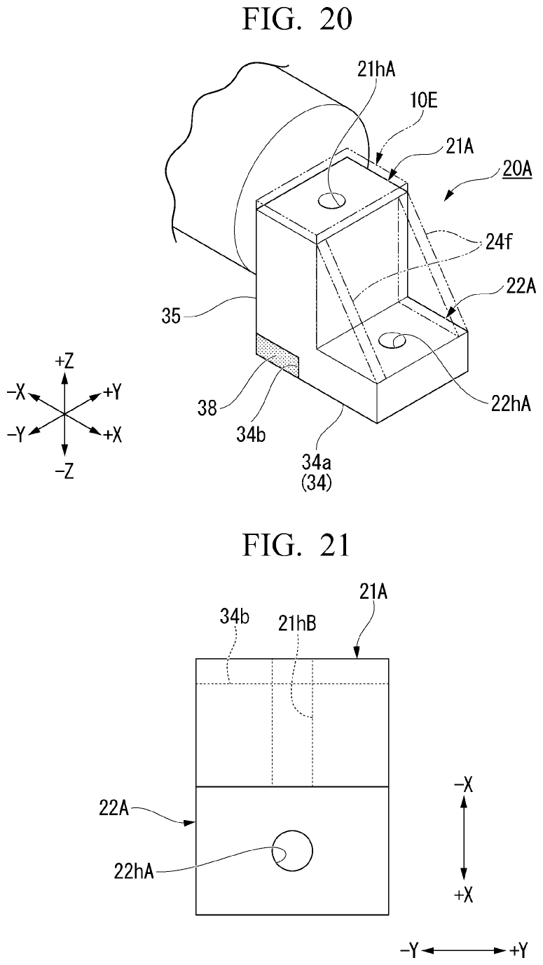

FIGS. 18 to 20 illustrate a structure for fixing the connection components 20, 30, and 100 of the present embodiment to the bus bar 42. FIG. 18 is a perspective view of the connection component 20A, FIG. 19 is a side view of the connection component 20A viewed from the Y direction, and FIG. 20 is a plan view of the connection component 20A viewed from the Z direction.

As illustrated in FIGS. 18 to 20, when viewed from the Y direction (third direction), a rectangular plane (hereinafter referred to as a front surface 21b) on the +X direction side of the first portion 21A and a rectangular plane (hereinafter referred to as an upper surface 22b) on the +Z direction side of the second portion 22A form an included angle θ1 of 90 degrees between the first portion 21A and the second portion 22A. The reference numeral R3 in the drawing denotes a concave region that is sandwiched between the front surface 21b and the upper surface 22b of the connection component 20A to form the included angle θ1. In the drawing, the reference numeral 21d denotes a rectangular plane (rear surface) on the −X direction side of the first portion 21A, and reference numeral 22d denotes a rectangular plane (lower surface) on the −Z direction side of the second portion 22A.

FIGS. 6 and 7 illustrate a constitution in which a pair of wall-shaped third portions 23 and 33 are provided at both ends in the Y direction of the region R3 forming the included angle θ1 in the connection components 20 and 30. The third portions 23 and 33 also function as the heat dissipation fins 24f in the connection components 20 and 30. Although not illustrated in detail, the connection component 100 in FIG. 14 also has the same constitution as that of the connection components 20 and 30. For the constitution of the connection component 100, the description of the connection component 30 may be replaced as described in paragraph 0107.

The second portions 22 and 32 of the connection components 20 and 30 have third attachment holes 22h and 32h penetrating the second portions 22 and 32 in the Z direction (first direction). Each of the third attachment holes 22h and 32h has a circular shape in a plan view viewed from the Z direction, and the centers of the third attachment holes 22h and 32h are respectively located at the centers in the width direction (the centers in the Y direction) of the second portions 22 and 32. The third attachment holes 22h and 32h allow fasteners such as bolts to be inserted thereinto such that the connection components 20 and 30 can be fastened (fixed) to the bus bar 42.

FIGS. 18 to 20 illustrate an example of a structure in which a connection target component (for example, the electronic component 10) 10D is fixed to the second attachment hole 21hB penetrating the first portion 21A in the X direction.

The first portion 21A illustrated in FIGS. 18 to 20 has a second attachment hole 21hB that penetrates the first portion 21A in the X direction (second direction) and through which the connection target component 10D is fastened. The second attachment hole 21hB has a circular shape in a front view viewed from the X direction. The center of the second attachment hole 21hB is disposed at the center in the width direction (center in the Y direction) of the first portion 21A, but may be disposed to be shifted from the center in the width direction.

The second portion 22A has a third attachment hole 22hA that penetrates the second portion 22A in the Z direction (first direction) and can be fastened to the bus bar 42. The third attachment hole 22hA has a circular shape in a plan view as viewed from the Z direction. The center of the third attachment hole 22hA is disposed at the center in the width direction (center in the Y direction) of the second portion 22A, but may be disposed to be shifted from the center in the width direction.

The connection component 20A includes a first end 34 facing the bus bar 42 in the Z direction and a second end 35 facing the connection target component 10D in the X direction. The first end 34 is a portion of the second portion 22A facing the upper surface 42s of the bus bar 42 (a portion on the lower surface 22d side). The second end 35 is a portion (a portion on the rear surface 21d side) of the first portion 21A facing the front surface (surface on the +X direction side) 10f of the connection target component 10D.

The first end 34 includes an abutting portion (a portion forming the lower surface 22d) 34a that abuts the upper surface 42s of the bus bar 42, and a recess 34b that is recessed in a direction (upward) away from the bus bar 42 in the Z direction with respect to the abutting portion 34a.

The recess 34b extends in the Y direction with a constant cross section and is open to both side surfaces of the connection component 20A in the Y direction. The recess 34b is provided at an intersection 36 between the first portion 21A and the second portion 22A. The recess 34b is formed at a corner portion 37 where the first end 34 and the second end 35 of the connection component 20A are coupled. The recess 34b is formed to notch the corner portion 37 when viewed from the Y direction. The reference numeral L1 in the drawing denotes a virtual ridge line formed when the rear surface 21d and the lower surface 22d of the connection component 20A intersect each other. The recess 34b and the ridge line LI extend in parallel with the Y direction.

The recess 34b has a rectangular cross section and extends in the Y direction. The recess 34b has a recess lower surface 34b1 displaced to the +Z direction side with respect to the lower surface 22d and a recess rear surface 34b2 displaced to the +X direction side with respect to the rear surface 21d. The recess 34b is open to the connection target component 10D side at the second end 35. The recess 34b is recessed in a direction (forward) away from the connection target component 10D in the X direction with respect to the rear surface 21d that abuts or approaches the front surface 10f of the connection target component 10D at the second end 35. The rear surface 21d side of the recess 34b may be closed by the connection target component 10D.

The recess 34b has a width 34tx in the X direction smaller than the thickness (plate thickness T1) of the first portion 21A in the X direction. That is, the recess 34b is formed within the width of the first portion 21A in the X direction. The recess 34b is formed by taking advantage of the thickness of the first portion 21A having the heat storage capacity. The recess 34b has a width 34tz in the Z direction smaller than the thickness (plate thickness T2) of the second portion 22A in the Z direction. That is, the recess 34b is formed within the width of the second portion 22A in the Z direction. The width of the recess 34b in the Z direction is suppressed, so that the second end 35 is made to easily receive heat from the connection target component 10D.

The recess 34b is filled with a heat transfer member 38 having a higher thermal conductivity than the connection component. Similarly to the heat transfer member 92, for example, the heat transfer member 38 is made of a thermally conductive silicone sheet or the like and is a molded article having elasticity cut into a predetermined shape. The heat transfer member 38 is inserted (filled) into the recess 34b in a compressed state. That is, in a state in which the connection component is fixed to the bus bar 42 and the connection target component 10D, and the cross-sectional shape of the recess 34b is closed, the heat transfer member 38 is compressed between the recess lower surface 34b1 and the upper surface 42s of the bus bar 42 in the Z direction, and is compressed between the recess rear surface 34b2 and the front surface 10f of the connection target component 10D in the X direction.

With this constitution, the heat transfer member 38 is in close contact with the connection target component 10D and the bus bar 42 while being in close contact with the recess, so that the heat stored in the connection component can be easily transferred to the bus bar 42, and the heat can be directly transferred from the connection target component 10D to the bus bar 42. The heat transfer member 38 is not limited to a molded article and may be formed of a thermally conductive gel or another material.

FIG. 21 illustrates an example of a structure in which a connection target component (the terminal 13 of the electronic component 10, and the second bus bars 75 and 76) 10E is fixed to a first attachment hole 21hA penetrating the first portion 21A in the Z direction.

As illustrated in FIG. 21, when a connection component is fixed to the bus bar 42 and the connection target component 10E, the rear surface 21d side of the cross-sectional shape of the recess 34b may be open. In this case, the heat transfer member 38 accommodated in the recess 34b is preferably a molded article.

As described above, the component connection structure of the embodiment includes the bus bar 42, the connection target components 10D and 10E, and the connection component 20A that connects the bus bar 42 to the connection target components 10D and 10E. The connection component 20A includes a first end 34 facing the bus bar 42 in the first direction (Z direction). The first end 34 includes an abutting portion 34a that abuts the bus bar 42 and a recess 34b that is recessed in a direction away from the bus bar 42 in the first direction with respect to the abutting portion 34a. The connection component 20A is fixed to the bus bar 42 in a state in which the recess 34b is filled with the heat transfer member 38 having a higher thermal conductivity than the connection component 20A.

According to this constitution, the recess 34b is provided in the first end 34 fixed to the bus bar 42 in the connection component 20A, and the connection component 20A is fixed to the bus bar 42 in a state in which the recess 34b is filled with the heat transfer member 38, whereby the heat stored in the connection component 20A is easily transferred to the bus bar 42 by the heat transfer member 38 while the connection component 20A is used as a heat storage member that receives the heat of the connection target components 10D and 10E. With this constitution, heat transfer properties between the connection component 20A and the bus bar 42 can be enhanced, and heat dissipation properties of the connection target components 10D and 10E can be enhanced.

In the component connection structure of the embodiment, the connection component 20A includes a first portion 21A extending in the first direction (Z direction) and a second portion 22A extending from the first portion 21A in the second direction (X direction) intersecting the first direction and including the first end 34, and the recess 34b is provided at an intersection 36 between the first portion 21A and the second portion 22A.

According to this constitution, the first portion 21A extending in the first direction is a portion extending along the connection target component 10D, and the intersection 36 between the first portion 21A and the second portion 22A extending along the bus bar 42 is filled with the heat transfer member 38 having a high thermal conductivity. Therefore, the heat of the connection target component 10D can be easily transferred to the first portion 21A, and the heat can be easily transferred from the second portion 22A to the bus bar 42.

In the component connection structure of the embodiment, in the connection component 20A, the thickness T1 of the first portion 21A in the second direction (X direction) is larger than the thickness T3 of the bus bar 42 in the first direction (Z direction), and the width 34tx of the recess 34b in the second direction is smaller than the thickness T1 of the first portion 21A in the second direction. According to this constitution, it is possible to increase the thickness of the first portion 21A in contact with the connection target component 10D to increase the heat storage capacity, and to provide the accommodation portion (recess 34b) of the heat transfer member 38 by taking advantage of the thickness of the first portion 21A.

In the component connection structure of the embodiment, the connection target component 10D and the connection component 20A are adjacent to each other in the second direction (X direction) intersecting the first direction (Z direction), the connection component 20A includes a second end 35 facing the connection target component 10D in the second direction, the recess 34b is provided at a corner portion 37 where the first end 34 and the second end 35 are connected, and the heat transfer member 38 is in contact with the connection target component 10D in a state in which the recess 34b is filled with the heat transfer member 38.

According to this constitution, since the heat transfer member 38 is in contact with the connection target component 10D, part of the heat of the connection target component 10D can be favorably transferred to the connection component 20A and the bus bar 42.

The connection component 20A of the embodiment connects the bus bar 42 to the connection target component 10D and includes a first end 34 facing the bus bar 42 in the first direction. The first end 34 includes an abutting portion 34a that abuts the bus bar 42 and a recess 34b recessed in a direction away from the bus bar 42 in the first direction with respect to the abutting portion 34a.

According to this constitution, while the connection component 20A functions as a heat storage member that receives the heat of the connection target component 10D, the recess 34b of the first end 34 facing the bus bar 42 is filled with the heat transfer member 38 having a high thermal conductivity, whereby the heat dissipation property of the connection target component 10D can be enhanced.

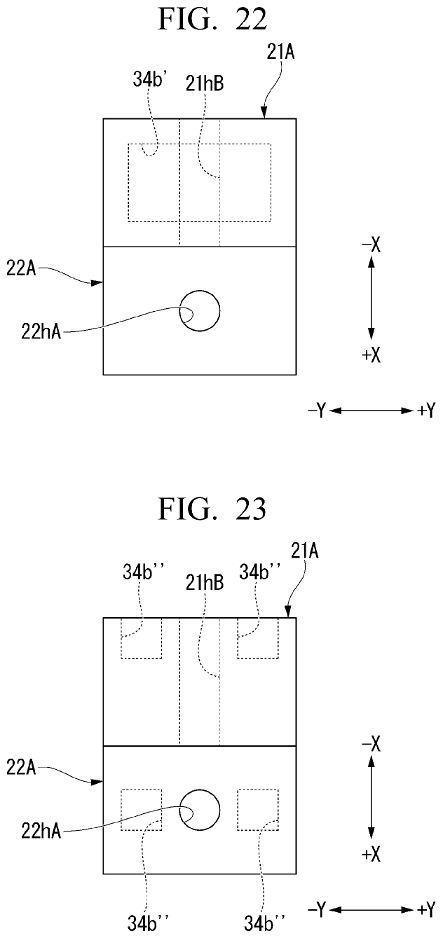

FIGS. 22 and 23 are plan views of the connection component 20A as viewed from the Z direction, and illustrate modification examples of the recess 34b.

A recess 34b′ illustrated in FIG. 22 is not open to both side surfaces of the connection component 20A in the Y direction and is also not open to the rear surface 21d of the connection component 20A. Since the recess 34b′ is closed in any of the X direction, the Y direction, and the Z direction when the connection component 20A is fixed to the bus bar 42, work is easily performed even in a case where the recess 34b′ is filled with the gel-like heat transfer member 38.

A recess 34b″ illustrated in FIG. 23 shows an aspect of being divided into a plurality of parts in the Y direction. The recess 34b″ formed within the width in the Y direction of the first portion 21A is open to the rear surface 21d but is not open to both side surfaces in the Y direction. For example, the recess 34b″ may be formed on the lower surface of the second portion 22A.

### Modification Examples

Next, several modification examples will be described. Note that a constitution other than that described below in each modification example is the same as the constitution of the above-described embodiment.

### (First Modification Example)

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### (Second Modification Example)

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by a part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### (Third Modification Example)

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed. For example, in this case, the accommodation portion 55 formed between the plurality of members corresponds to an example of an “accommodation portion recessed in the first direction (Z direction)”.

### (Fourth Modification Example)

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiment and the modification examples are not limited to the examples described above. For example, a plurality of embodiments may be implemented in combination with each other.

### DESCRIPTION OF REFERENCE SYMBOLS

1 Electrical connection unit
10D, 10E Connection target component
20A Connection component
21A First portion
22A Second portion
34 First end
34a Abutting portion
34b Recess
34tx Width in second direction
35 Second end
36 Intersection
37 Corner portion
38 Heat transfer member
42 Bus bar
T1 Thickness in second direction
T3 Thickness in first direction

1. A component connection structure comprising: a bus bar; a connection target component; and a connection component that connects the bus bar and the connection target component,
wherein the connection component includes a first end facing the bus bar in a first direction,
wherein the first end includes: an abutting portion that abuts the bus bar; and a recess that is recessed in a direction away from the bus bar in the first direction with respect to the abutting portion, and
wherein the connection component is fixed to the bus bar in a state in which the recess is filled with a heat transfer member having a higher thermal conductivity than the connection component.

2. The component connection structure according to claim 1,
wherein the connection component includes:
a first portion extending in the first direction, and
a second portion extending from the first portion in a second direction intersecting the first direction and including the first end, and
wherein the recess is provided at an intersection between the first portion and the second portion.

3. The component connection structure according to claim 2,
wherein, in the connection component,
a thickness of the first portion in the second direction is larger than a thickness of the bus bar in the first direction, and
a width of the recess in the second direction is smaller than the thickness of the first portion in the second direction.

4. The component connection structure according to claim 1,
wherein the connection target component and the connection component are adjacent to each other in a second direction intersecting the first direction,
wherein the connection component includes a second end facing the connection target component in the second direction,
wherein the recess is provided at a corner portion where the first end and the second end are connected, and
wherein the heat transfer member is in contact with the connection target component in a state in which the recess is filled with the heat transfer member.

5. A connection component for connecting a bus bar and a connection target component, the connection component comprising:
a first end facing the bus bar in a first direction,
wherein the first end includes: an abutting portion that abuts the bus bar; and a recess that is recessed in a direction away from the bus bar in the first direction with respect to the abutting portion.
